(19) United States
(12) Patent Application Publication
(10) Pub. No.: US 2025/0393287 A1
(43) Pub. Date: Dec. 25, 2025

(54) SEMICONDUCTOR DEVICE

(71) Applicant: ROHM CO., LTD., Kyoto-shi (JP)

(72) Inventors: Masaki AONO, Kyoto-shi (JP); Kohei MURASAKI, Kyoto-shi (JP); Kazuma MORIYAMA, Kyoto-shi (JP)

(73) Assignee: ROHM CO., LTD., Kyoto-shi (JP)

(21) Appl. No.: 19/312,384

(22) Filed: Aug. 28, 2025

Related U.S. Application Data
(63) Continuation of application No. PCT/JP2024/006575, filed on Feb. 22, 2024.

(30) Foreign Application Priority Data
Mar. 9, 2023 (JP) 2023-036384

(51) Int. Cl. H10D 64/27; H10D 12/00

(52) U.S. Cl. CPC H10D 64/518; H10D 12/481; H10D 64/513

(57) ABSTRACT

A semiconductor device includes a semiconductor chip having a first principal surface and a second principal surface opposite to the first principal surface, and a trench-type IGBT structure formed on the first principal surface of the semiconductor chip, wherein the IGBT structure includes a trench formed in the first principal surface of the semiconductor chip and extending in a plurality of directions, an insulating film formed on a side surface of the trench, an embedded conductor embedded inside the trench through the insulating film, and an intersection portion formed by the trenches extending in the plurality of directions, and a curvature index of a corner portion of the intersection portion is 1.5 μm or more.

### CROSS-REFERENCE TO RELATED APPLICATIONS

The present application is a bypass continuation of International Application No. PCT/JP2024/006575 filed Feb. 22, 2024, which corresponds to Japanese Patent Application No. 2023-036384 filed on Mar. 9, 2023 in the Japan Patent Office, and the entire disclosure of these applications are incorporated herein by reference.

### TECHNICAL FIELD

The present disclosure relates to a semiconductor device having a trench-type IGBT structure.

### BACKGROUND ART

Patent Literature 1 (WO 2020/080476) discloses a reverse conducting-insulated gate bipolar transistor (RC-IGBT) as an example of a semiconductor device.

### BRIEF DESCRIPTION OF DRAWINGS

FIG. 1 is a schematic plan view of a semiconductor device according to a preferred embodiment of the present disclosure.

FIG. 2 is a plan view illustrating a layout example of a plurality of IGBT regions, a boundary region, a gate electrode, and an emitter electrode.

FIG. 3 is a plan view illustrating a layout example of a gate wiring, a boundary well region, and an outer peripheral well region.

FIG. 4 is an enlarged view of a portion surrounded by an alternate long and short dashed line IV in FIG. 2.

FIG. 5 is an enlarged view of a portion surrounded by an alternate long and short dashed line V in FIG. 4.

FIG. 6 is a cross-sectional view taken along line VI-VI shown in FIG. 4.

FIG. 7 is a cross-sectional view taken along line VII-VII shown in FIG. 4.

FIG. 8 is an enlarged view of a portion surrounded by an alternate long and short dashed line VIII in FIG. 7.

FIG. 9 is a cross-sectional view taken along line IX-IX shown in FIG. 5.

FIG. 10 is an enlarged view of a portion surrounded by an alternate long and short dashed line X in FIG. 6.

FIG. 11 is an enlarged view of a portion surrounded by an alternate long and short dashed line XI in FIG. 2.

FIG. 12A is a cross-sectional view taken along line XIIA-XIIA shown in FIG. 11.

FIG. 12B is an enlarged view of a portion surrounded by an alternate long and short dashed line XIIB in FIG. 11.

FIG. 13 is a schematic cross-sectional view for describing a curvature index.

FIGS. 14A to 22A and 14B to 22B are diagrams illustrating a part of a manufacturing process of a semiconductor device according to a preferred embodiment of the present disclosure.

FIG. 23 is a diagram for describing a patterning mask.

FIG. 24 is a graph showing a relationship between a chamfer width of the patterning mask and the curvature index.

FIG. 25 is a diagram showing test results when an electrostatic breakdown resistance test (ESD resistance test) was performed on Example 1, Example 2, and Reference Examples 1 to 4.

FIGS. 26A to 26C are diagrams showing test results when a time-zero dielectric breakdown resistance test (TZBD resistance test) was performed on Reference Examples 1 to 3, respectively.

FIGS. 27A to 27C are diagrams showing test results when an electrostatic breakdown resistance test was performed on Reference Example 4, Example 1, and Example 2, respectively.

FIG. 28 is a graph showing a relationship between a TCE processing time and a side etching amount of a trench.

FIGS. 29A to 29C are diagrams showing test results when a time-zero dielectric breakdown resistance test (TZBD resistance test, 78 V) was performed on Reference Example 5, Example 3, and Example 4.

FIGS. 30A and 30B are diagrams showing test results when a time-zero dielectric breakdown resistance test (TZBD resistance test, 84 V) was performed on Reference Example 5, Example 3, and Example 4.

FIGS. 31A and 31B are diagrams showing test results when a time-zero dielectric breakdown resistance test (TZBD resistance test, 86 V) was performed on Reference Example 5, Example 3, and Example 4.

FIG. 32 is a view corresponding to FIG. 5, which is a cross-sectional view for describing a modification of the present disclosure.

### DESCRIPTION OF EMBODIMENTS

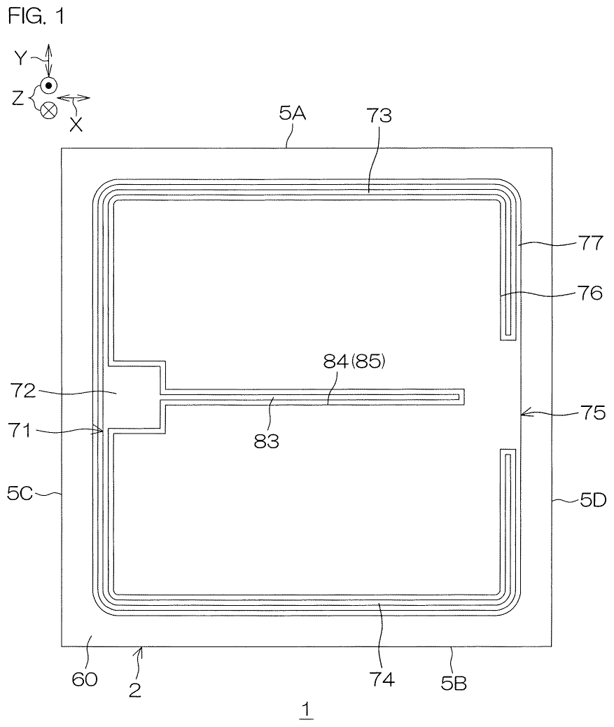

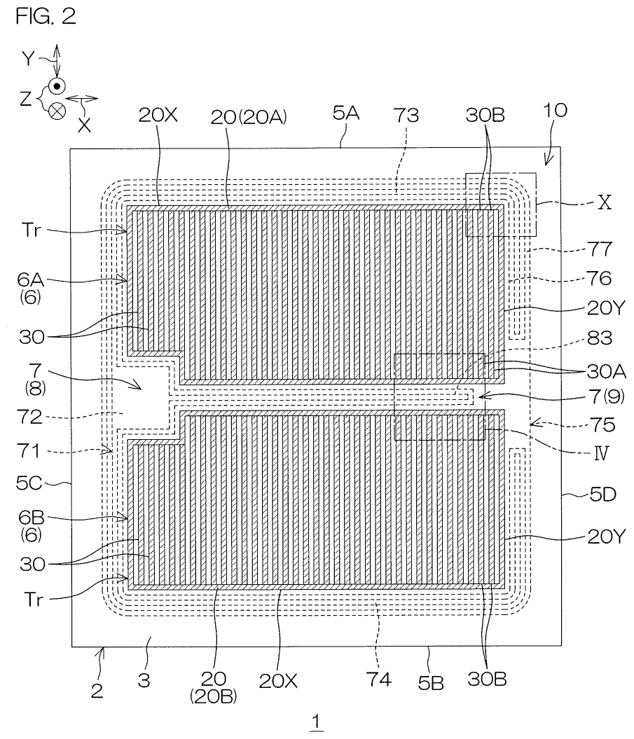

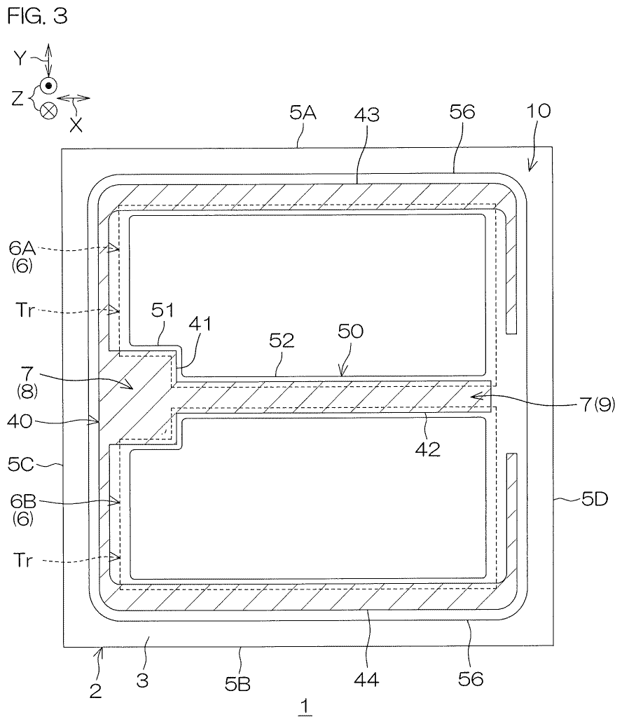

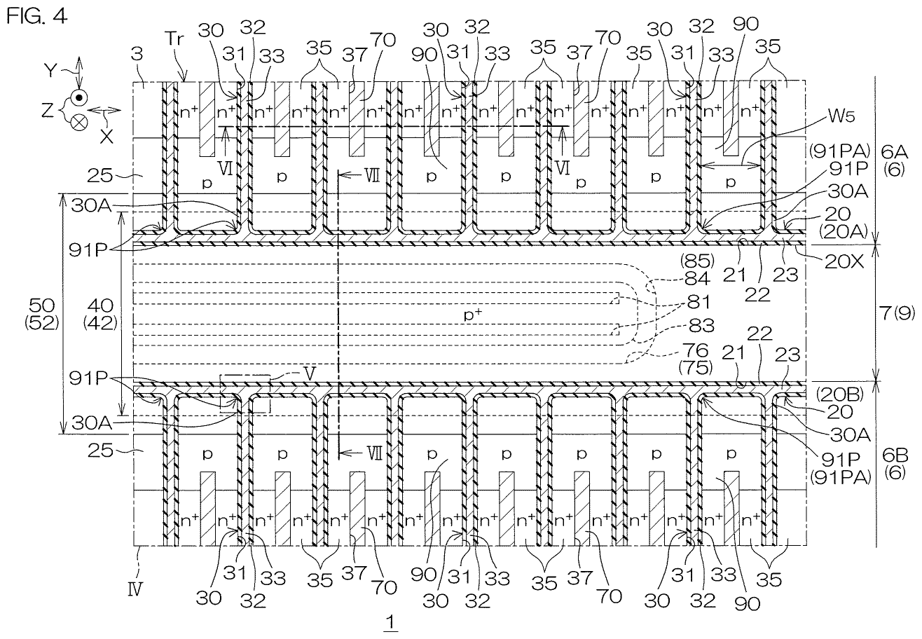

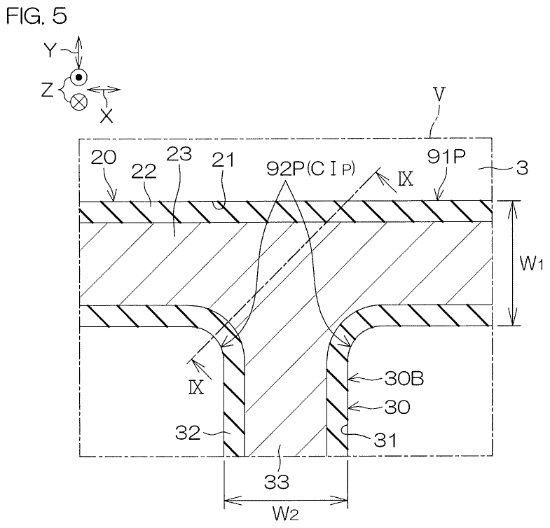

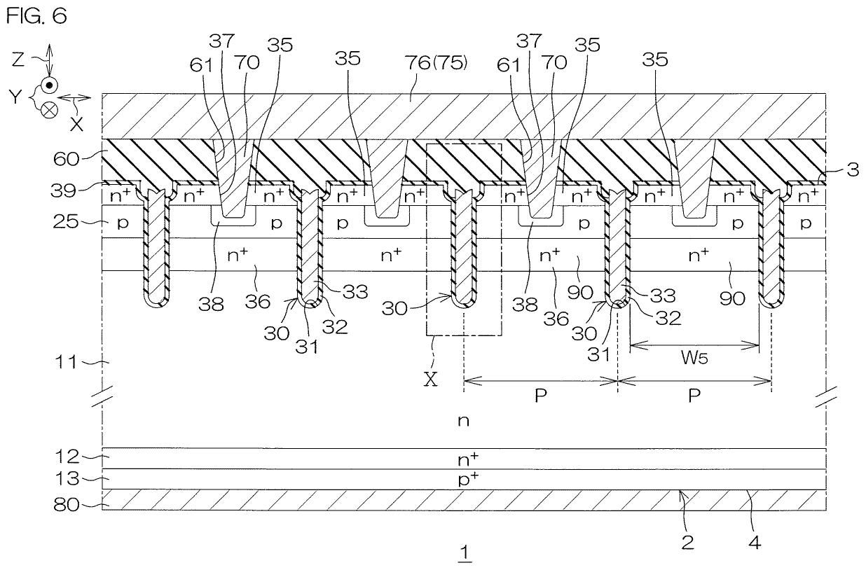

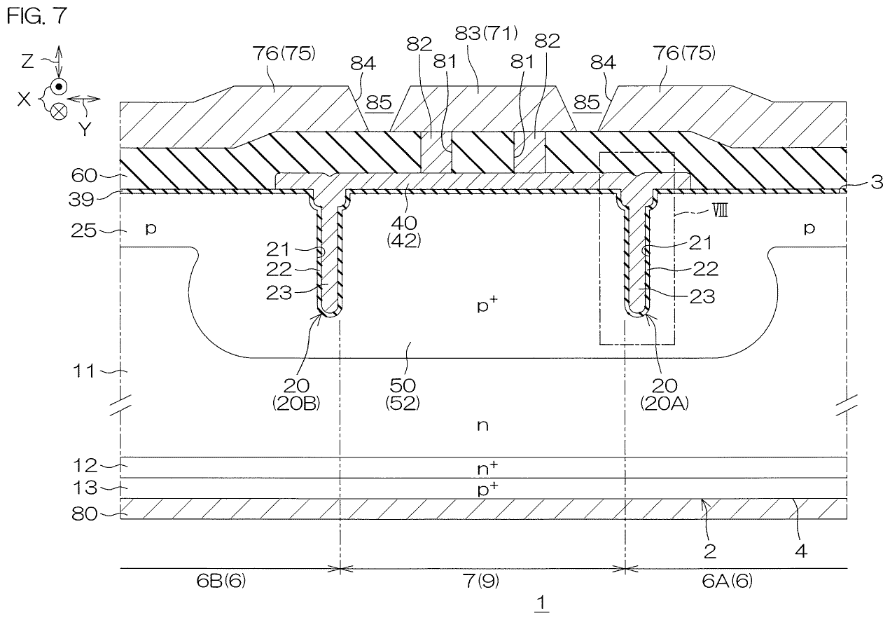

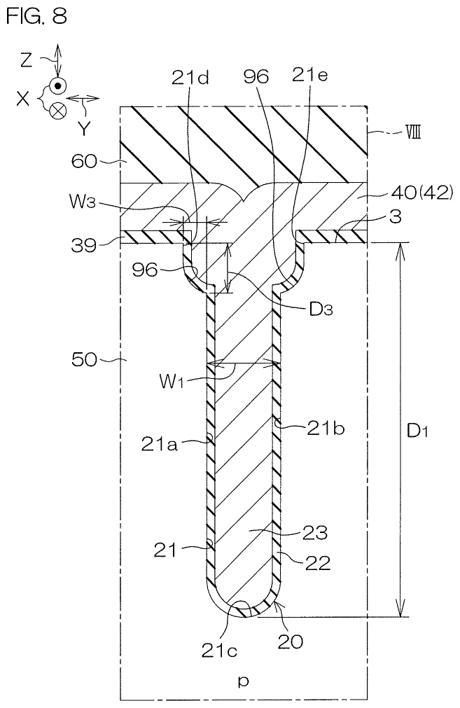

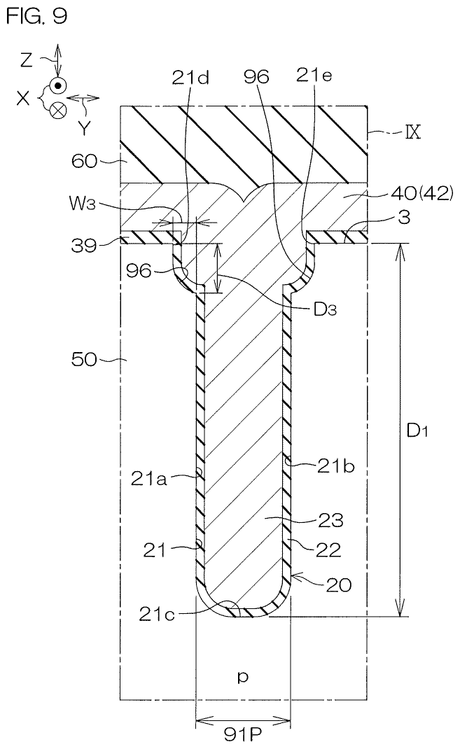

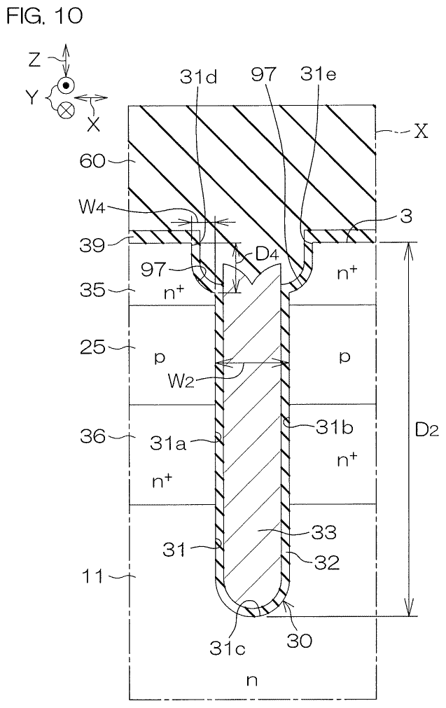

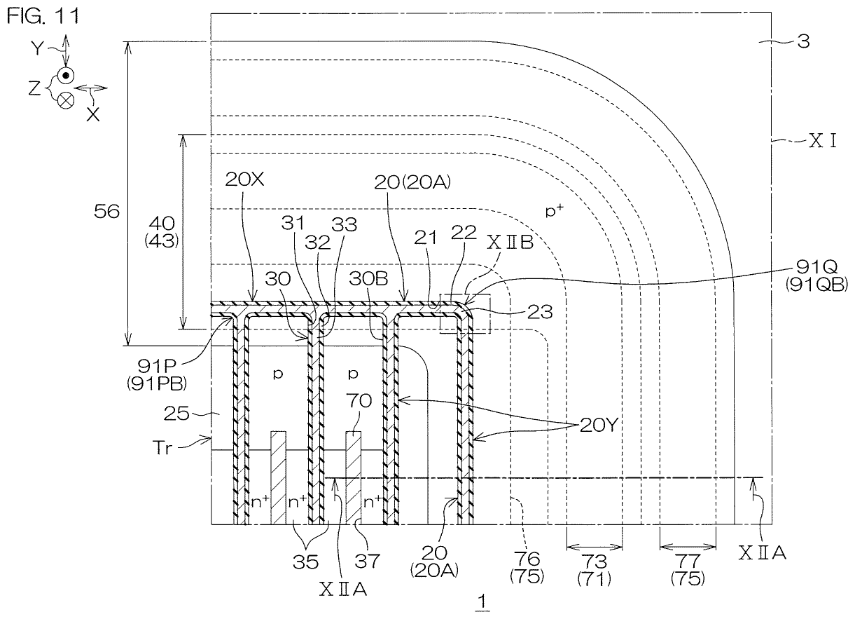

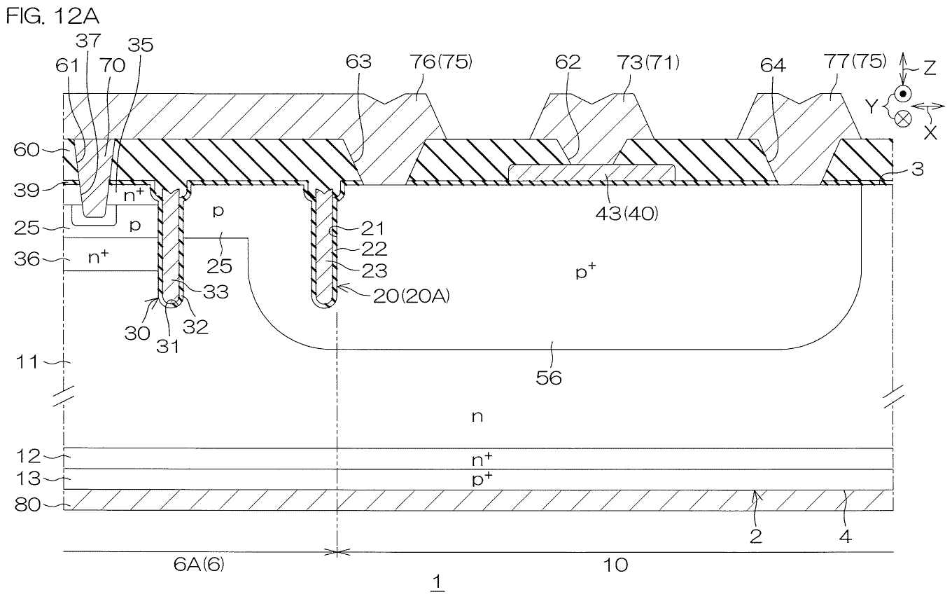

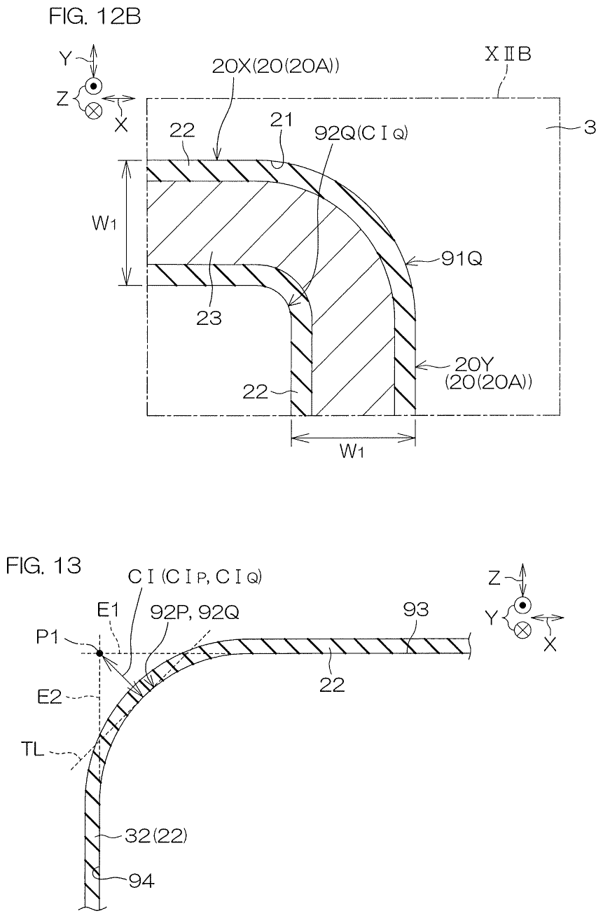

FIG. 1 is a schematic plan view of a semiconductor device 1 according to a preferred embodiment of the present disclosure. FIG. 2 is a plan view illustrating a layout example of a plurality of IGBT regions 6, a boundary region 7, a gate electrode 71, and an emitter electrode 75. FIG. 3 is a plan view illustrating a layout example of a gate wiring 40, a boundary well region 50, and an outer peripheral well region 56. FIG. 4 is an enlarged view of a portion surrounded by an alternate long and short dashed line IV in FIG. 2. FIG. 5 is an enlarged view of a portion surrounded by an alternate long and short dashed line V in FIG. 4. FIG. 6 is a cross-sectional view taken along line VI-VI shown in FIG. 4. FIG. 7 is a cross-sectional view taken along line VII-VII shown in FIG. 4. FIG. 8 is an enlarged view of a portion surrounded by an alternate long and short dashed line VIII in FIG. 7. FIG. 9 is a cross-sectional view taken along line IX-IX shown in FIG. 5. FIG. 10 is an enlarged view of a portion surrounded by an alternate long and short dashed line X in FIG. 6. FIG. 11 is an enlarged view of a portion surrounded by an alternate long and short dashed line XI in FIG. 2. FIG. 12A is a cross-sectional view taken along line XIIA-XIIA shown in FIG. 11. FIG. 12B is an enlarged view of a portion surrounded by an alternate long and short dashed line XIIB in FIG. 11. FIG. 13 is a schematic plan view for describing a curvature index CI.

A semiconductor device 1 is an IGBT semiconductor device including an insulated gate bipolar transistor (IGBT).

As illustrated in FIGS. 1 to 3, the semiconductor device 1 includes a semiconductor chip 2 of rectangular parallelepiped shape. The semiconductor chip 2 has a first principal surface 3 at one side, a second principal surface 4 at another side, and side surfaces 5A, 5B, 5C, and 5D connecting the first principal surface 3 and the second principal surface 4. The first principal surface 3 and the second principal surface 4 are each formed in a quadrangular shape in plan view as viewed in a normal direction Z thereto (hereinafter, simply referred to as “plan view”). The normal direction Z is also a thickness direction of the semiconductor chip 2.

The first side surface 5A and the second side surface 5B extend in a first direction X that is oriented along the first principal surface 3 and oppose each other in a second direction Y that intersects (specifically, is orthogonal to) the first direction X. The third side surface 5C and the fourth side surface 5D extend in the second direction Y and oppose each other in the first direction X. The semiconductor chip 2 has a single layer structure constituted of a silicon single-crystal substrate.

The semiconductor chip 2 has, for example, a square shape in plan view. The size of the semiconductor chip 2 is, for example, 0.5 mm square or more and 20 mm square or less. A chip size of “X mm square” may mean that the length of one side of the square semiconductor chip 2 is X mm.

As illustrated in FIGS. 2 and 3, the semiconductor device 1 includes a plurality of IGBT regions 6 formed at intervals in the second direction Y on the first principal surface 3. Each IGBT region 6 includes a trench-type IGBT structure (transistor structure) Tr. The IGBT region 6 may be referred to as an “active region.” The plurality of IGBT regions 6 include a first IGBT region 6A and a second IGBT region 6B.

As illustrated in FIGS. 2 and 3, the first IGBT region 6A is formed in a region on the first side surface 5A side with respect to a straight line crossing the center of the first principal surface 3 in the first direction X. The second IGBT region 6B is formed in a region on the second side surface 5B side with respect to the straight line crossing the center of the first principal surface 3 in the first direction X. In the present preferred embodiment, the plurality of IGBT regions 6 are each formed in a quadrangular annular shape having four sides parallel to the first to fourth side surfaces 5A to 5D in plan view.

As illustrated in FIGS. 2 and 3, the semiconductor device 1 further includes a boundary region 7 formed in a region between the plurality of IGBT regions 6. Specifically, the boundary region 7 is provided in a band shape extending in the first direction X in a region between the first IGBT region 6A and the second IGBT region 6B. In the examples of FIGS. 2 and 3, the boundary region 7 is located on the straight line crossing the center of the first principal surface 3 in the first direction X.

As illustrated in FIGS. 2 and 3, the boundary region 7 includes a first boundary region 8 having a relatively large width in the second direction Y and a second boundary region 9 having a smaller width than the first boundary region 8 in the second direction Y. The first boundary region 8 is provided in a region on one side (third side surface 5C side) in the first direction X as a portion that supports a terminal electrode. The first boundary region 8 may be referred to as a “pad region,” a “wide region,” or a “terminal support region.”

In the present preferred embodiment, the first boundary region 8 is located on the straight line crossing the center of the first principal surface 3 in the first direction X in plan view, and is provided in a quadrangular shape in the vicinity of a central portion of the third side surface 5C. A width of the first boundary region 8 may be 100 μm or more and 800 μm or less. The width of the first boundary region 8 is preferably 200 μm or more and 600 μm or less. In the present preferred embodiment, the width of the first boundary region 8 is set in a range of 350 μm or more and 450 μm or less.

The second boundary region 9 is formed in a region on the other side (fourth side surface 5D side) in the first direction X with respect to the first boundary region 8 as a portion that supports wiring. The second boundary region 9 is located on the straight line crossing the center of the first principal surface 3 in the first direction X, and is drawn out in a band shape from the first boundary region 8 toward a central portion side of the fourth side surface 5D. The second boundary region 9 may be referred to as a “street region,” a “narrow region,” or a “wiring support region.”

As illustrated in FIGS. 2 and 3, the semiconductor device 1 further includes an outer peripheral region 10. The outer peripheral region 10 collectively surrounds the plurality of IGBT regions 6. The outer peripheral region 10 has a quadrangular annular shape extending along the first to fourth side surfaces 5A to 5D. The outer peripheral region 10 forms a non-active region together with the boundary region 7. In the present preferred embodiment, an IGBT structure Tr to be described later is not formed in the boundary region 7 and the outer peripheral region 10.

As illustrated in FIGS. 6, 7, and 12A, the semiconductor device 1 includes an n-type (first conductivity type) drift region 11. The drift region 11 is formed in an entire region of the interior of the semiconductor chip 2. In the present preferred embodiment, the semiconductor chip 2 is made of an n-type semiconductor substrate, and the drift region 11 is formed using the semiconductor substrate.

As illustrated in FIGS. 6, 7, and 12A, the semiconductor device 1 further includes an n-type buffer region 12 formed in a surface layer portion of the second principal surface 4. In the present preferred embodiment, the buffer region 12 is formed in a layer shape extending along the second principal surface 4 in an entire region of the second principal surface 4. The buffer region 12 has a higher n-type impurity concentration than the drift region 11. The presence or absence of the buffer region 12 is arbitrary, and an embodiment without the buffer region 12 may be adopted instead.

As illustrated in FIGS. 6, 7, and 12A, the semiconductor device 1 includes a p-type (second conductivity type) collector region 13 formed in the surface layer portion of the second principal surface 4. In the present preferred embodiment, the collector region 13 is formed in a surface layer portion of the buffer region 12 on the second principal surface 4 side. In the present preferred embodiment, the collector region 13 is formed in a layer shape extending along the second principal surface 4 in the entire region of the second principal surface 4. The collector region 13 is exposed from the second principal surface 4 and a part of the first to fourth side surfaces 5A to 5D.

As illustrated in FIGS. 2 and 4, the semiconductor device 1 further includes a plurality of trench separation structures 20 formed on the first principal surface 3 such that the plurality of IGBT regions 6 are demarcated. A gate potential is applied to the plurality of trench separation structures 20. The trench separation structures 20 may be referred to as “trench gate separating structures” or “trench gate connection structures.” The plurality of trench separation structures 20 include a first trench separation structure 20A and a second trench separation structure 20B.

As illustrated in FIGS. 2 and 4, the first trench separation structure 20A surrounds the first IGBT region 6A and demarcates the first IGBT region 6A from the boundary region 7 and the outer peripheral region 10. In the present preferred embodiment, the first trench separation structure 20A is formed in a polygonal annular shape having four sides parallel to the peripheral edge of the semiconductor chip 2 in plan view. The first trench separation structure 20A has a portion bent such that the first boundary region 8 and the second boundary region 9 of the boundary region 7 are demarcated in plan view.

As illustrated in FIGS. 2 and 4, the second trench separation structure 20B surrounds the second IGBT region 6B and demarcates the second IGBT region 6B from the boundary region 7 and the outer peripheral region 10. In the present preferred embodiment, the second trench separation structure 20B is formed in a polygonal annular shape having four sides parallel to the peripheral edge of the semiconductor chip 2 in plan view. The second trench separation structure 20B has a portion bent such that the first boundary region 8 and the second boundary region 9 of the boundary region 7 are demarcated in plan view.

As illustrated in FIGS. 2, 4, and 11, each of the trench separation structures 20A and 20B includes at least two first direction portions 20X extending in the first direction X and at least two second direction portions 20Y extending in the second direction Y. An end portion of the first direction portion 20X and an end portion of the second direction portion 20Y are mechanically and electrically connected. The end portion of the first direction portion 20X and the end portion of the second direction portion 20Y intersect in an L shape to form corner portions of the polygonal annular trench separation structures 20A and 20B.

Hereinafter, a configuration of a single trench separation structure 20 shall be described. In the description of the trench separation structure 20, FIGS. 8 and 9 each illustrate a cross section of the trench separation structure 20. FIG. 8 is a cross section in a direction orthogonal to the long direction of the trench separation structure 20, and FIG. 9 is a cross section in a direction crossing a T-shaped intersection portion 91P (described later) of the trench separation structure 20.

As illustrated in FIGS. 7 to 9, the trench separation structure 20 includes a separation trench 21 (first trench), a separation insulating film 22, and a separation embedded electrode (embedded conductor) 23. The separation trench 21 is dug in from the first principal surface 3 toward the second principal surface 4, and demarcates a wall surface of the trench separation structure 20.

The separation trench 21 is formed in the first principal surface 3. The separation trench 21 is formed in a vertical shape in cross-sectional view. The separation trench 21 includes a pair of side surfaces 21a and 21b that oppose each other and a bottom surface 21c connecting the pair of side surfaces 21a and 21b. The bottom surface 21c has a round shape bulging toward the second principal surface 4 side in cross-sectional view.

As illustrated in FIG. 8, the separation trench 21 has a first width W₁. The first width W₁ is a width (maximum value) in a direction orthogonal to the direction in which the separation trench 21 extends. The first width W₁ is preferably a width less than the width of the second boundary region 9. The first width W₁ is preferably 0.5 μm or more and 2.0 μm or less. More specifically, the first width W₁ may be 1.0 μm.

The separation trench 21 has a first depth D₁. The first depth D₁ may be 1 μm or more and 30 μm or less. The first depth D₁ is preferably 4 μm or more and 15 μm or less. The first depth D₁ is particularly preferably 6 μm or more and 10 μm or less. The separation trench 21 may be formed in a tapered shape in which the width decreases toward the second principal surface 4 in cross-sectional view. The bottom surface 21c may be a flat surface parallel to the first principal surface 3.

As illustrated in FIGS. 8 and 9, first recess portions 96 recessed toward the side surfaces 21a and 21b sides of the separation trench 21 are formed at opening ends 21d and 21e of the separation trench 21. A cross-sectional shape of the first recess portion 96 is an arc shape recessed toward the side surface 21a or 21b side of the separation trench 21. The first recess portion 96 has a third width W₃. The third width W₃ is a width in the second direction Y between a point where the extension line of the side surface 21a or 21b intersects the first principal surface 3 and an end portion of the first recess portion 96. The third width W₃ is 1350 Å or more and 2000 Å or less. The first recess portion 96 has a third depth D₃. The third depth D₃ is larger than the third width W₃. The third depth D₃ is 1850 Å or more. A ratio (W₃/W₁) of the third width W₃ to the first width W₁ of the separation trench 21 is 0.14 or more and 0.2 or less.

As illustrated in FIGS. 7 to 9, the separation insulating film 22 is formed in a film shape along the side surfaces 21a and 21b of the separation trench 21. The separation insulating film 22 demarcates a recess space in the separation trench 21. The separation insulating film 22 may include at least one among a silicon oxide film, a silicon nitride film, a silicon oxynitride film, and an aluminum oxide film. The separation insulating film 22 preferably has a single layer structure constituted of a single insulating film. The separation insulating film 22 particularly preferably includes a silicon oxide film that is constituted of the oxide of the semiconductor chip 2.

As illustrated in FIGS. 7 to 9, the separation embedded electrode 23 is embedded in the separation trench 21 with the separation insulating film 22 interposed therebetween. The separation embedded electrode 23 is constituted of conductive polysilicon in the present preferred embodiment. The gate potential is applied to the separation embedded electrode 23.

Hereinafter, a structure in the plurality of IGBT regions 6 will be described. The structure on the second IGBT region 6B side is substantially the same as the structure on the first IGBT region 6A side. Specifically, the structure on the second IGBT region 6B side is line-symmetric with the structure on the first IGBT region 6A side with respect to the boundary region 7. Hereinafter, the structure on the first IGBT region 6A side will be described. The description of the structure on the first IGBT region 6A side is applied to the description of the structure on the second IGBT region 6B side, which can be omitted.

As illustrated in FIGS. 6 and 7, the semiconductor device 1 includes a p-type base region 25 formed in a surface layer portion of the first principal surface 3 in the first IGBT region 6A. The base region 25 may be referred to as a “body region” or a “channel region.” The base region 25 is formed at a depth position shallower than the trench separation structure 20, and has a bottom portion located further toward the first principal surface 3 side than a bottom wall of the trench separation structure 20. The base region 25 extends in a layer shape along the first principal surface 3 and is connected to an inner peripheral wall of the trench separation structure 20.

As illustrated in FIGS. 2 and 4, the semiconductor device 1 includes a plurality of trench structures 30. The gate potential is applied to the plurality of trench structures 30. The plurality of trench structures 30 penetrate the base region 25 and reach the drift region 11. The plurality of trench structures 30 are aligned at intervals in the first direction X in plan view and are each formed in a band shape extending in the second direction Y. That is, the plurality of trench structures 30 are aligned in a stripe shape extending in the second direction Y.

As illustrated in FIGS. 4 and 11, each of the plurality of trench structures 30 has a first end portion 30A on the boundary region 7 side and a second end portion 30B on the outer peripheral region 10 side in the long direction (second direction Y). The first end portion 30A and the second end portion 30B are mechanically and electrically connected to the trench separation structure 20. That is, the plurality of trench structures 30, together with the trench separation structure 20, constitute a single trench gate structure of ladder shape. A connecting portion of the trench structure 30 and the trench separation structure 20 may be considered a part of the trench separation structure 20 or a part of the trench structure 30.

Hereinafter, a configuration of single trench structure 30 will be described.

As illustrated in FIGS. 6 and 10, the trench structure 30 includes a gate trench 31 (second trench), a gate insulating film 32, and a gate embedded electrode (embedded conductor) 33. The gate trench 31 is dug in from the first principal surface 3 toward the second principal surface 4, and demarcates a wall surface of the trench structure 30.

The gate trench 31 is formed in the first principal surface 3. The gate trench 31 is formed in a vertical shape in cross-sectional view. The gate trench 31 includes a pair of side surfaces 31a and 31b that oppose each other and a bottom surface 31c connecting the pair of side surfaces 31a and 31b. The bottom surface 31c has a round shape bulging toward the second principal surface 4 side in cross-sectional view. In the present preferred embodiment, the gate trench 31 communicates with the separation trench 21 at both ends (the first end portion 30A and the second end portion 30B) in the second direction Y. Specifically, a side wall of the gate trench 31 communicates with a side wall of the separation trench 21, and a bottom wall of the gate trench 31 communicates with a bottom wall of the separation trench 21.

As illustrated in FIG. 6, the plurality of gate trenches 31 are aligned at a constant pitch P in the first direction X. The pitch P of the plurality of gate trenches 31 is preferably less than the width of the second boundary region 9 of the boundary region 7. The pitch P of the plurality of gate trenches 31 may be 5 μm or more and 30 μm or less. The pitch P of the plurality of gate trenches 31 is preferably 10 μm or more and 20 μm or less. The pitch P of the plurality of gate trenches 31 is preferably 15 μm.

As illustrated in FIG. 10, the gate trench 31 has a second width W₂. The second width W₂ is a width (maximum value) in a direction orthogonal to the direction in which the gate trench 31 extends. The second width W₂ is preferably 0.5 μm or more and 2.0 μm or less. More specifically, the second width W₂ may be 1.0 μm. The second width W₂ may be substantially equal to the first width W₁.

As illustrated in FIG. 10, the gate trench 31 has a second depth D₂. The second depth D₂ may be 1 μm or more and 30 μm or less. The second depth D₂ is preferably 4 μm or more and 15 μm or less. The second depth D₂ is particularly preferably 6 μm or more and 10 μm or less. The second depth D₂ is preferably substantially equal to the first depth D₁. The gate trench 31 may be formed in a tapered shape in which the width decreases toward the second principal surface 4 in cross-sectional view. The bottom surface 31c may be a flat surface parallel to the first principal surface 3.

As illustrated in FIG. 10, second recess portions 97 recessed toward the side surfaces 31a and 31b sides of the gate trench 31 are formed at opening ends 31d and 31e of the gate trench 31. The cross-sectional shape of the second recess portion 97 is an arc shape recessed toward the side surface 31a or 31b side of the gate trench 31. The second recess portion 97 has a fourth width W₄. The fourth width W₄ is a width in the first direction X between a point where the extension line of the side surface 31a or 31b intersects the first principal surface 3 and an end portion of the second recess portion 97. The fourth width W₄ is 1350 Å or more and 2000 Å or less. The second recess portion 97 has a fourth depth D₄. The fourth depth D₄ is larger than the fourth width W₄. The fourth depth D₄ is 1850 Å or more. A ratio (W₄/W₂) of the fourth width W₄ to the second width W₂ of the gate trench 31 is 0.14 or more and 0.2 or less. A ratio (W₄/P) of the fourth width W₄ to the pitch P (described later) of the plurality of gate trenches 31 is 0.009 or more and 0.0133 or less. A ratio (W₄/W₅) of the fourth width W₄ to a fifth width W₅ (described later) of a mesa portion 90 (described later) is 0.011 or more and 0.017 or less.

As illustrated in FIGS. 6 and 10, the gate insulating film 32 is formed in a film shape along a wall surface of the gate trench 31. The gate insulating film 32 demarcates a recess space in the gate trench 31. The thickness of the gate insulating film 32 is, for example, 50 nm or more and 200 nm or less.

The gate insulating film 32 may include at least one among a silicon oxide film, a silicon nitride film, a silicon oxynitride film, and an aluminum oxide film. The gate insulating film 32 preferably has a single layer structure constituted of a single insulating film. The gate insulating film 32 particularly preferably includes a silicon oxide film that is constituted of the oxide of the semiconductor chip 2. In the present preferred embodiment, the gate insulating film 32 is constituted of the same insulating film as the separation insulating film 22. The gate insulating film 32 is connected to the separation insulating film 22 at a communication portion between the separation trench 21 and the gate trench 31.

As illustrated in FIGS. 6 and 10, the gate embedded electrode 33 is embedded in the gate trench 31 with the gate insulating film 32 interposed therebetween. The gate embedded electrode 33 is constituted of conductive polysilicon in the present preferred embodiment. The gate potential is applied to the gate embedded electrode 33. The gate embedded electrode 33 is connected to the separation embedded electrode 23 at the communication portion between the separation trench 21 and the gate trench 31.

As illustrated in FIGS. 4 and 6, the semiconductor device 1 further includes a plurality of n-type emitter regions 35 formed in a surface layer portion of the base region 25. Each of the plurality of emitter regions 35 has a higher n-type impurity concentration than the drift region 11. The plurality of emitter regions 35 are formed on both sides of the plurality of trench structures 30, respectively. The plurality of emitter regions 35 are each formed in a band shape extending along the plurality of trench structures 30 in plan view. As a matter of course, the plurality of emitter regions 35 may be formed at intervals along the plurality of trench structures 30 in plan view.

As illustrated in FIG. 6, the semiconductor device 1 further includes a plurality of n-type carrier storage regions 36 formed in a region immediately below the base region 25 in the semiconductor chip 2. The plurality of carrier storage regions 36 suppress discharge of carriers (holes) to the base region 25 and promote accumulation of carriers (holes) in a region immediately below the plurality of trench structures 30. That is, the plurality of carrier storage regions 36 promote low on-resistance and low on-voltage from the inside of the semiconductor chip 2.

The plurality of carrier storage regions 36 are disposed on both sides of the plurality of trench structures 30, and are each formed in a band shape extending along the plurality of trench structures 30 in plan view. The plurality of carrier storage regions 36 are each formed in a region between the bottom portion of the base region 25 and a bottom wall of the trench structure 30 in the thickness direction of the semiconductor chip 2. The plurality of carrier storage regions 36 are preferably separated from the bottom wall of the trench structure 30 toward the base region 25 side. Bottom portions of the plurality of carrier storage regions 36 are preferably located closer to the bottom wall side of the trench structure 30 than an intermediate portion of the trench structure 30. The plurality of carrier storage regions 36 have a higher n-type impurity concentration than the drift region 11. The n-type impurity concentration of the plurality of carrier storage regions 36 is preferably lower than that of the emitter region 35. The presence or absence of the carrier storage region 36 is arbitrary. Therefore, an embodiment without the carrier storage region 36 may be adopted instead.

As illustrated in FIG. 6, the semiconductor device 1 includes a plurality of contact holes 37 formed in the first principal surface 3 such that the emitter region 35 is exposed. The plurality of contact holes 37 are formed on both sides of the plurality of trench structures 30 at intervals in the first direction X from the plurality of trench structures 30. As illustrated in FIG. 6, each of the plurality of contact holes 37 may be formed in a convergent shape that narrows in opening width from an opening toward a bottom wall.

As illustrated in FIG. 6, the plurality of contact holes 37 may be separated from a bottom portion of the emitter region 35 toward the first principal surface 3 side so as not to reach the base region 25. As a matter of course, the plurality of contact holes 37 may penetrate the emitter region 35 to reach the base region 25. The plurality of contact holes 37 are each formed in a band shape extending along the plurality of trench structures 30 in plan view. In the long direction (second direction Y), the plurality of contact holes 37 are shorter than the plurality of trench structures 30.

As illustrated in FIG. 6, the semiconductor device 1 includes a plurality of p-type contact regions 38 formed in a region different from the plurality of emitter regions 35 in the surface layer portion of the base region 25. Each of the plurality of contact regions 38 is formed in a band shape extending along the corresponding contact hole 37 in plan view. Bottom portions of the plurality of contact regions 38 are each formed in a region between the bottom wall of the corresponding contact hole 37 and the bottom portion of the base region 25. The plurality of contact regions 38 have a higher p-type impurity concentration than that of the base region 25.

As described above, the IGBT structure Tr (see FIGS. 2 and 4) includes the base region 25, the plurality of trench structures 30, the plurality of emitter regions 35, the plurality of carrier storage regions 36, the plurality of contact holes 37, and the plurality of contact regions 38.

As illustrated in FIG. 4, the semiconductor device 1 includes a plurality of mesa portions 90 demarcated in the first IGBT region 6A. The plurality of mesa portions 90 are demarcated by the gate trench 31. Each mesa portion 90 is demarcated in a region between a pair of gate trenches 31 adjacent to each other in the first direction X. The mesa portion 90 is formed of a part of the semiconductor chip 2. Each of the plurality of mesa portions 90 extends in a band shape extending in the second direction Y and is demarcated at intervals in the first direction X. That is, the plurality of mesa portions 90 are formed in a stripe shape extending in the second direction Y.

As illustrated in FIG. 4, the mesa portion 90 has a fifth width W₅. The fifth width W₅ is a width (maximum value) in a direction orthogonal to the direction in which the mesa portion 90 extends. The fifth width W₅ is preferably a width less than the width of the second boundary region 9. The fifth width W₅ may be 11 μm or more and 21 μm or less. The fifth width W₅ is preferably 11 μm or more and 16 μm or less. The fifth width W₅ is preferably 14 μm.

As illustrated in FIGS. 3 and 4, the semiconductor device 1 includes a p-type boundary well region 50 formed in the surface layer portion of the first principal surface 3 in the boundary region 7. In the present preferred embodiment, the boundary well region 50 has a higher p-type impurity concentration than the plurality of base regions 25. As a matter of course, the boundary well region 50 may have a lower p-type impurity concentration than the plurality of base regions 25. The boundary well region 50 is formed in a region sandwiched by the first trench separation structure 20A and the second trench separation structure 20B. The boundary well region 50 extends in the first direction X along the boundary region 7 in plan view.

As illustrated in FIG. 3, the boundary well region 50 includes a first boundary well region 51 formed in the first boundary region 8 of the boundary region 7 and a second boundary well region 52 formed in the second boundary region 9 of the boundary region 7. The first boundary well region 51 has a relatively large region width in the second direction Y. The first boundary well region 51 is formed in a quadrangular shape in plan view. The first boundary well region 51 is preferably formed in an entire region of the first boundary region 8.

As illustrated in FIGS. 3 and 4, the second boundary well region 52 has a region width smaller than the region width of the first boundary well region 51 in the second direction Y, and is drawn out in a band shape from the first boundary well region 51 toward the second boundary region 9. In the present preferred embodiment, the second boundary well region 52 is located on the straight line crossing the center of the first principal surface 3 in the first direction X.

As illustrated in FIG. 7, the boundary well region 50 is formed deeper than the base region 25. The boundary well region 50 is preferably formed deeper than the plurality of trench separation structures 20. As illustrated in FIG. 4, in the present preferred embodiment, the boundary well region 50 has a width larger than the width of the boundary region 7 in the second direction Y, and is drawn out from the boundary region 7 into the plurality of IGBT regions 6.

As illustrated in FIG. 7, the boundary well region 50 is connected to the plurality of trench separation structures 20 adjacent in the second direction Y. The boundary well region 50 has a portion that covers the bottom walls of the plurality of trench separation structures 20. The boundary well region 50 has a portion that covers the bottom walls of the plurality of trench structures 30 across the plurality of trench separation structures 20.

As illustrated in FIG. 7, the boundary well region 50 covers a side wall of the trench separation structure 20 in each IGBT region 6. Although not illustrated, the boundary well region 50 covers side walls of the plurality of trench structures 30 in each IGBT region 6. As illustrated in FIGS. 4 and 7, the boundary well region 50 is connected to each base region 25 in the surface layer portion of the first principal surface 3.

As illustrated in FIGS. 3 and 11, the semiconductor device 1 includes a p-type outer peripheral well region 56 formed in the surface layer portion of the first principal surface 3 in the outer peripheral region 10. In the present preferred embodiment, the outer peripheral well region 56 has a higher p-type impurity concentration than the plurality of base regions 25. As a matter of course, the outer peripheral well region 56 may have a lower p-type impurity concentration than the plurality of base regions 25. The p-type impurity concentration of the outer peripheral well region 56 is preferably substantially equal to the p-type impurity concentration of the boundary well region 50.

As illustrated in FIGS. 3 and 12A, the outer peripheral well region 56 is formed in a layer shape extending along the first principal surface 3 and is exposed from the first principal surface 3. The outer peripheral well region 56 is formed at an interval inward from the peripheral edge (first to fourth side surfaces 5A to 5D) of the first principal surface 3. The outer peripheral well region 56 is formed in a band shape extending along the plurality of IGBT regions 6 in plan view. In the present preferred embodiment, the outer peripheral well region 56 is formed in an annular shape surrounding the plurality of IGBT regions 6 in plan view. Specifically, the outer peripheral well region 56 is formed in a quadrangular annular shape having four sides parallel to the peripheral edge of the first principal surface 3.

As illustrated in FIG. 12A, the outer peripheral well region 56 is formed deeper than the plurality of base regions 25. The outer peripheral well region 56 is particularly preferably formed deeper than the plurality of trench separation structures 20 (the plurality of trench structures 30). The outer peripheral well region 56 has a depth that is substantially equal to the boundary well region 50 in the present preferred embodiment.

As illustrated in FIG. 12A, the outer peripheral well region 56 is connected to the plurality of trench separation structures 20. The outer peripheral well region 56 has a portion that covers the bottom walls of the plurality of trench separation structures 20. The outer peripheral well region 56 is drawn out from the outer peripheral region 10 into each IGBT region 6 (see FIG. 3). The outer peripheral well region 56 has a portion that covers the bottom walls of the plurality of trench structures 30 across the plurality of trench separation structures 20.

As illustrated in FIGS. 4 and 11, the IGBT structure Tr includes a plurality of T-shaped intersection portions 91P formed at the connection portion between the trench separation structure 20 and the trench structure 30. The plurality of T-shaped intersection portions 91P include a plurality of first T-shaped intersection portions 91PA (FIG. 4) formed at a connection portion between the first end portion 30A of the trench structure 30 and the first direction portion 20X on the boundary region 7 side of the trench separation structure 20 and a plurality of second T-shaped intersection portions 91PB (FIG. 11) formed at a connection portion between the second end portion 30B of the trench structure 30 and the first direction portion 20X on the outer peripheral region 10 side of the trench separation structure 20.

As illustrated in FIG. 4, the plurality of first T-shaped intersection portions 91PA oppose a boundary wiring 42 and the boundary well region 50 (second boundary well region 52) in the thickness direction of the semiconductor chip 2. As illustrated in FIG. 11, the plurality of second T-shaped intersection portions 91PB oppose a first outer peripheral wiring 43 and the outer peripheral well region 56 in the thickness direction of the semiconductor chip 2.

As illustrated in FIG. 5, the T-shaped intersection portion 91P has two corner portions 92P. A curvature index CI_{P} of each corner portion 92P is 1.5 μm or more and 2.4 μm or less. The curvature index CI_{P} is a curvature index CI of the corner portion 92P (see FIG. 13).

As illustrated in FIG. 13, the curvature index CI is an index to define the curvature of the corner portion (corner portion 92P, corner portion 92Q). The corner portion (corner portion 92P, corner portion 92Q) is formed by a first side 93 and a second side 94. Specifically, the curvature index CI is the shortest distance between the corner portion (corner portion 92P, corner portion 92Q) and an intersection P1 of an extension line E1 of the first side 93 forming the corner portion (corner portion 92P, corner portion 92Q) and an extension line E2 of the second side 94 orthogonal to the extension line E1 and forming the corner portion (corner portion 92P, corner portion 92Q). In other words, it is the shortest distance between a tangent line TL at the corner portion (corner portion 92P, corner portion 92Q) intersecting both the extension line E1 and the extension line E2 at 45° and the intersection P1.

In the T-shaped intersection portion 91P, a ratio (CI_{P}/W₁) of the curvature index CI_{P} of the corner portion 92P to the first width W₁ of the separation trench 21 is 1.5 or more and 2.4 or less. In the T-shaped intersection portion 91P, a ratio (CI_{P}/W₂) of the curvature index CI_{P} of the corner portion 92P to the second width W₂ of the plurality of gate trenches 31 is 1.5 or more and 2.4 or less. In the T-shaped intersection portion 91P, a ratio (CI_{P}/P) of the curvature index CI_{P} of the corner portion 92P to the pitch P of the plurality of gate trenches 31 is 0.1 or more and 0.16 or less. In the T-shaped intersection portion 91P, a ratio (CI_{P}/W₅) of the curvature index CI_{P} of the corner portion 92P to the fifth width W₅ of the mesa portion 90 is 0.11 or more and 0.17 or less.

As illustrated in FIG. 11, the IGBT structure Tr includes a plurality of L-shaped intersection portions 91Q formed at a connection portion between the first direction portion 20X of the trench separation structure 20 and the second direction portion 20Y of the trench separation structure 20. The plurality of L-shaped intersection portions 91Q include a plurality of first L-shaped intersection portions 91 (not illustrated) formed at the connection portion between the first direction portion 20X and the second direction portion 20Y on the boundary region 7 side of the trench separation structure 20, and a plurality of second L-shaped intersection portions 91QB formed at the connection portion between the first direction portion 20X and the second direction portion 20Y on the outer peripheral region 10 side of the trench separation structure 20.

The plurality of first L-shaped intersection portions 91 (not illustrated) oppose the boundary wiring 42 and the boundary well region 50 (second boundary well region 52) in the thickness direction of the semiconductor chip 2. The plurality of second L-shaped intersection portions 91QB oppose the first outer peripheral wiring 43 and the outer peripheral well region 56 in the thickness direction of the semiconductor chip 2.

As illustrated in FIG. 12B, the L-shaped intersection portion 91Q has one corner portion 92Q. A curvature index of the corner portion 92Q is 1.5 μm or more and 2.4 μm or less. The curvature index CI_{Q} is a curvature index CI of the corner portion 92Q (see FIG. 13).

In the L-shaped intersection portion 91Q, a ratio (CI_{Q}/W₁) of the curvature index CI_{Q} of the corner portion 92Q to the first width W₁ of the separation trench 21 is 1.5 or more and 2.4 or less. In the L-shaped intersection portion 91Q, a ratio (CI_{Q}/W₂) of the curvature index CI_{Q} of the corner portion 92Q to the second width W₂ of the plurality of gate trenches 31 is 1.5 or more and 2.4 or less. In the L-shaped intersection portion 91Q, a ratio (CI_{Q}/P) of the curvature index CI_{Q} of the corner portion 92Q to the pitch P of the plurality of gate trenches 31 is 0.1 or more and 0.16 or less. In the L-shaped intersection portion 91Q, a ratio (CI_{Q}/W₅) of the curvature index CI_{Q} of the corner portion 92Q to the fifth width W₅ of the mesa portion 90 is 0.11 or more and 0.17 or less.

As illustrated in FIGS. 6, 7, and 12A, the semiconductor device 1 includes a principal surface insulating film 39 covering the first principal surface 3. The thickness of the principal surface insulating film 39 is, for example, 50 nm or more and 200 nm or less.

The principal surface insulating film 39 may include at least one among a silicon oxide film, a silicon nitride film, a silicon oxynitride film, and an aluminum oxide film. The principal surface insulating film 39 preferably has a single layer structure constituted of a single insulating film. The principal surface insulating film 39 particularly preferably includes a silicon oxide film that is constituted of the oxide of the semiconductor chip 2. In the present preferred embodiment, the principal surface insulating film 39 is constituted of the same insulating film as the gate insulating film 32.

As illustrated in FIGS. 6, 7, and 12A, the principal surface insulating film 39 extends in a film shape along the first principal surface 3 such that the plurality of IGBT regions 6, the boundary region 7, and the outer peripheral region 10 are covered. The principal surface insulating film 39 may be continuous with the peripheral edge (first to fourth side surfaces 5A to 5D) of the semiconductor chip 2.

As illustrated in FIGS. 6 and 7, the principal surface insulating film 39 covers the first principal surface 3 such that the plurality of trench separation structures 20 and the plurality of trench structures 30 are exposed. Specifically, the principal surface insulating film 39 is connected to the separation insulating film 22 and the gate insulating film 32 to expose the separation embedded electrode 23 and the gate embedded electrode 33.

As illustrated in FIG. 7, the semiconductor device 1 includes a gate wiring 40 disposed on the first principal surface 3 of the semiconductor chip 2. Specifically, the gate wiring 40 is disposed in a film shape on the principal surface insulating film 39. The gate wiring 40 is constituted of a conductive polysilicon film in the present preferred embodiment.

As illustrated in FIG. 3, the gate wiring 40 is routed to at least the boundary region 7. In the present preferred embodiment, the gate wiring 40 is routed to the boundary region 7 and the outer peripheral region 10 in an arbitrary layout. Specifically, the gate wiring 40 includes a pad wiring 41, the boundary wiring 42, the first outer peripheral wiring 43, and a second outer peripheral wiring 44. The pad wiring 41 is disposed on the first boundary region 8 of the boundary region 7 and has a relatively large first wiring width in the second direction Y. In the present preferred embodiment, the pad wiring 41 is formed in a quadrangular shape in plan view. The pad wiring 41 has a width larger than the width of the boundary region 7 (the width of the first boundary region 8) in the second direction Y. The pad wiring 41 is drawn out from above the boundary region 7 to above the plurality of trench separation structures 20 adjacent in the second direction Y.

As illustrated in FIG. 3, in the present preferred embodiment, the pad wiring 41 is drawn out from above the boundary region 7 to above the plurality of IGBT regions 6. As a result, the pad wiring 41 is mechanically and electrically connected to the separation embedded electrode 23 and the plurality of gate embedded electrodes 33, and transmits the gate potential to the separation embedded electrode 23 and the gate embedded electrodes 33. In the present preferred embodiment, the pad wiring 41 is integrally formed with the separation embedded electrode 23 and the plurality of gate embedded electrodes 33.

As illustrated in FIGS. 3 and 4, the boundary wiring 42 is drawn out from the pad wiring 41 to above the second boundary region 9 of the boundary region 7, and has a second wiring width smaller than the first wiring width of the pad wiring 41 in the second direction Y. The boundary wiring 42 is formed in a band shape extending in the first direction X. In the present preferred embodiment, the boundary wiring 42 crosses the center of the semiconductor chip 2. The boundary wiring 42 has a width larger than the width of the boundary region 7 (the width of the second boundary region 9) in the second direction Y. The boundary wiring 42 is drawn out from above the boundary region 7 to above the plurality of trench separation structures 20 adjacent in the second direction Y.

As illustrated in FIG. 4, in the present preferred embodiment, the boundary wiring 42 is drawn out from above the boundary region 7 to above the plurality of IGBT regions 6 such that the first end portions 30A of the plurality of trench structures 30 are covered. As a result, the boundary wiring 42 is mechanically and electrically connected to the separation embedded electrode 23 and the plurality of gate embedded electrodes 33, and transmits the gate potential to the separation embedded electrode 23 and the gate embedded electrodes 33. In the present preferred embodiment, the boundary wiring 42 is integrally formed with the separation embedded electrode 23 and the plurality of gate embedded electrodes 33.

As illustrated in FIG. 3, the first outer peripheral wiring 43 is drawn out from the pad wiring 41 to above the outer peripheral region 10, and is formed in a band shape extending along the first side surface 5A and the third side surface 5C. The first outer peripheral wiring 43 may have a portion extending in a band shape along the fourth side surface 5D. The first outer peripheral wiring 43 has a portion drawn out from above the outer peripheral region 10 to above the first trench separation structure 20A in a portion extending along the first side surface 5A. As illustrated in FIG. 11, in the present preferred embodiment, the first outer peripheral wiring 43 also covers the second end portions 30B of the plurality of trench structures 30 in the first IGBT region 6A.

As a result, the first outer peripheral wiring 43 is mechanically and electrically connected to the separation embedded electrode 23 and the plurality of gate embedded electrodes 33. In the present preferred embodiment, the first outer peripheral wiring 43 is integrally formed with the separation embedded electrode 23 and the plurality of gate embedded electrodes 33. The first outer peripheral wiring 43 transmits the gate potential from the outer peripheral region 10 side to the separation embedded electrode 23 and the gate embedded electrodes 33.

As illustrated in FIG. 3, the second outer peripheral wiring 44 is drawn out from the pad wiring 41 to above the outer peripheral region 10, and is formed in a band shape extending along the second side surface 5B and the third side surface 5C. The second outer peripheral wiring 44 may have a portion extending in a band shape along the fourth side surface 5D. The second outer peripheral wiring 44 has a portion drawn out from above the outer peripheral region 10 to above the second trench separation structure 20B in a portion extending along the second side surface 5B. Although not illustrated, the second outer peripheral wiring 44 also covers the second end portions 30B of the plurality of trench structures 30 in the second IGBT region 6B in the present preferred embodiment.

As a result, the second outer peripheral wiring 44 is mechanically and electrically connected to the separation embedded electrode 23 and the plurality of gate embedded electrodes 33. In the present preferred embodiment, the second outer peripheral wiring 44 is integrally formed with the separation embedded electrode 23 and the plurality of gate embedded electrodes 33. The second outer peripheral wiring 44 transmits the gate potential from the outer peripheral region 10 side to the separation embedded electrode 23 and the gate embedded electrodes 33.

The semiconductor device 1 further includes an interlayer insulating film 60 covering the principal surface insulating film 39. The interlayer insulating film 60 may include at least one among a silicon oxide film, a silicon nitride film, a silicon oxynitride film, and an aluminum oxide film. The interlayer insulating film 60 may include at least one among a non-doped silicate glass (NSG) film, a phosphor silicate glass (PSG) film, and a boron phosphor silicate glass (BPSG) film as an example of a silicon oxide film. The interlayer insulating film 60 may have a single layer structure constituted of a single insulating film or a laminated structure including a plurality of insulating films. The interlayer insulating film 60 has a thickness exceeding the thickness of the principal surface insulating film 39. The thickness of the interlayer insulating film 60 is, for example, 1.0 μm or more and 2.5 μm or less.

As illustrated in FIGS. 6, 7, and 12A, the interlayer insulating film 60 may extend in a layer shape along the first principal surface 3 and be continuous with the peripheral edge (first to fourth side surfaces 5A to 5D) of the semiconductor chip 2. The interlayer insulating film 60 selectively covers the plurality of IGBT regions 6, the boundary region 7, and the outer peripheral region 10. The interlayer insulating film 60 covers the principal surface insulating film 39, the plurality of trench separation structures 20, and the plurality of trench structures 30 in each IGBT region 6. The interlayer insulating film 60 covers the principal surface insulating film 39 and the gate wiring 40 in the boundary region 7 and the outer peripheral region 10.

As illustrated in FIG. 6, the interlayer insulating film 60 has a plurality of contact openings 61 that expose the plurality of emitter regions 35 in each IGBT region 6. In the present preferred embodiment, the plurality of contact openings 61 are formed in one-to-one correspondence with the plurality of contact holes 37, and communicate with the corresponding contact holes 37. Each of the plurality of contact openings 61 is formed in a band shape extending along the corresponding contact hole 37 in plan view.

The interlayer insulating film 60 includes at least one gate opening that selectively exposes the gate wiring 40 in the boundary region 7 and/or the outer peripheral region 10. In the present preferred embodiment, the gate opening may expose the boundary wiring 42, the first outer peripheral wiring 43, and the second outer peripheral wiring 44. FIG. 12A illustrates only a gate opening 62 that exposes the first outer peripheral wiring 43.

As illustrated in FIG. 12A, the interlayer insulating film 60 includes at least one first well opening 63 (a plurality of first well openings 63 in the present preferred embodiment) that selectively exposes an inner edge portion of the outer peripheral well region 56 in the outer peripheral region 10. Specifically, the plurality of first well openings 63 expose the inner edge portion of the outer peripheral well region 56 in a region between the plurality of trench separation structures 20 and the gate wiring 40.

As illustrated in FIG. 12A, the interlayer insulating film 60 includes at least one (one in the present preferred embodiment) second well opening 64 that selectively exposes an outer edge portion of the outer peripheral well region 56 in the outer peripheral region 10. Specifically, the second well opening 64 exposes the outer edge portion of the outer peripheral well region 56 in a region on the peripheral edge side of the first principal surface 3 with respect to the gate wiring 40. The second well opening 64 is formed in a band shape extending along the plurality of IGBT regions 6. In the present preferred embodiment, the second well opening 64 is formed in a quadrangular annular shape surrounding the plurality of IGBT regions 6.

As illustrated in FIG. 7, the interlayer insulating film 60 includes at least one boundary gate opening 81 (two boundary gate openings 81 in the present preferred embodiment) (see also FIG. 4) that exposes the boundary wiring 42 of the gate wiring 40. In the present preferred embodiment, each of the plurality of boundary gate openings 81 is formed in a band shape extending in the first direction X, and is formed at an interval in the second direction Y. A planar shape of the boundary gate opening 81 is arbitrary. The boundary gate opening 81 may be formed in a circular shape, an elliptical shape, a quadrangular shape, or a polygonal shape in plan view. The plurality of boundary gate openings 81 may be aligned at intervals in the first direction X. Also, the number of boundary gate openings 81 is arbitrary.

As illustrated in FIGS. 4, 6, and 12A, the semiconductor device 1 includes a plurality of via electrodes 70 embedded in the interlayer insulating film 60 such as to be electrically connected to the plurality of emitter regions 35. Specifically, the plurality of via electrodes 70 are embedded in the plurality of contact openings 61 of the interlayer insulating film 60. The plurality of via electrodes 70 include a portion in contact with the semiconductor chip 2 and a portion in contact with the interlayer insulating film 60. The plurality of via electrodes 70 are electrically connected to the emitter region 35 and the contact region 38 in the portion in contact with the semiconductor chip 2.

Each via electrode 70 may include at least one among a Ti-based metal film, a W-based metal film, an Al-based metal film, and a Cu-based metal film. The Ti-based metal may include at least one of a pure Ti film (Ti film having a purity of 99% or more) and a Ti alloy film. The Ti alloy film may be a TiN film. The W-based metal may include at least one of a pure W film (W film having a purity of 99% or more) and a W alloy film. The AI-based metal may include at least one of a pure Al film (Al film having a purity of 99% or more) and an Al alloy film. The Al alloy film may contain at least one among an AlCu alloy, an AlSi alloy, and an AlSiCu alloy. The Cu-based metal may include at least one of a pure Cu film (Cu film having a purity of 99% or more) and a Cu alloy film. Each via electrode 70 may have a laminated structure including the Ti-based metal film and the W-based metal film.

As illustrated in FIG. 7, the semiconductor device 1 includes a plurality of gate via electrodes 82 embedded in the plurality of boundary gate openings 81 such as to be mechanically and electrically connected to the boundary wiring 42. Each gate via electrode 82 may include at least one among a Ti-based metal film, a W-based metal film, an Al-based metal film, and a Cu-based metal film. Similarly to the via electrode 70, each gate via electrode 82 may have a laminated structure including the Ti-based metal film and the W-based metal film. The plurality of gate via electrodes 82 preferably oppose the gate wiring 40 (boundary wiring 42) and the boundary well region 50 (second boundary well region 52) in the thickness direction of the semiconductor chip 2.

As illustrated in FIGS. 1 and 2, the semiconductor device 1 includes a gate electrode 71 disposed on the interlayer insulating film 60 such as to be electrically connected to the gate wiring 40. The gate electrode 71 is constituted of a conductive material different from the gate wiring 40. In the present preferred embodiment, the gate electrode 71 is constituted of a metal film and has a lower resistance value than the gate wiring 40. The gate electrode 71 may be referred to as a “gate metal.” The gate electrode 71 may include at least one among a Ti-based metal film, a W-based metal film, an Al-based metal film, and a Cu-based metal film. The gate electrode 71 may have a laminated structure including the Ti-based metal film and the Al-based metal film.

As illustrated in FIGS. 1 and 3, the gate electrode 71 is disposed immediately above the gate wiring 40. The gate electrode 71 can be routed to an arbitrary region of the plurality of IGBT regions 6, the boundary region 7, and the outer peripheral region 10 in an arbitrary layout according to the layout of the gate wiring 40. In the present preferred embodiment, the gate electrode 71 includes a gate pad electrode 72, a first gate finger electrode 73, a second gate finger electrode 74, and a boundary gate finger electrode 83.

For example, the gate electrode 71 and the IGBT structure Tr facing the gate electrode 71 through the interlayer insulating film 60 constitute a capacitor. A capacitance (gate capacitance) of the capacitor as the entire gate is 300 pF or less.

As illustrated in FIGS. 1 and 3, the gate pad electrode 72 is disposed immediately above the pad wiring 41 of the gate wiring 40. The gate pad electrode 72 enters a gate opening (not illustrated) from above the interlayer insulating film 60, and is electrically connected to the pad wiring 41. In the present preferred embodiment, the gate pad electrode 72 is formed in a quadrangular shape in plan view.

As illustrated in FIGS. 1 and 3, the gate pad electrode 72 opposes the first boundary well region 51 of the boundary well region 50 in the thickness direction of the semiconductor chip 2. The gate pad electrode 72 is preferably formed at an interval from the trench separation structure 20 and the plurality of trench structures 30 in plan view. The gate pad electrode 72 preferably has a planar area smaller than the planar area of the first boundary well region 51 of the boundary well region 50. The gate pad electrode 72 particularly preferably has a planar area smaller than the planar area of the pad wiring 41.

As illustrated in FIGS. 1 and 3, the first gate finger electrode 73 is drawn out from the gate pad electrode 72 to immediately above the first outer peripheral wiring 43. The first gate finger electrode 73 is formed in a band shape extending along the first outer peripheral wiring 43. In the present preferred embodiment, the first gate finger electrode 73 extends in a band shape along the first side surface 5A and the third side surface 5C.

As illustrated in FIG. 12A, the first gate finger electrode 73 enters the gate opening 62 from above the interlayer insulating film 60, and is electrically connected to the first outer peripheral wiring 43. The first gate finger electrode 73 opposes the outer peripheral well region 56 in the thickness direction of the semiconductor chip 2. The first gate finger electrode 73 is preferably formed at an interval from the trench separation structure 20 and the plurality of trench structures 30 in plan view.

As illustrated in FIGS. 1 and 3, the second gate finger electrode 74 is drawn out from the gate pad electrode 72 to immediately above the second outer peripheral wiring 44. The second gate finger electrode 74 is formed in a band shape extending along the second outer peripheral wiring 44. In the present preferred embodiment, the second gate finger electrode 74 extends in a band shape along the second side surface 5B and the third side surface 5C.

The second gate finger electrode 74 is electrically connected to the second outer peripheral wiring 44 from above the interlayer insulating film 60 through a gate opening (not illustrated). When a via electrode similar to the via electrode 70 is embedded in the gate opening, the second gate finger electrode 74 may be electrically connected to the second outer peripheral wiring 44 through the via electrode.

The second gate finger electrode 74 opposes the outer peripheral well region 56 in the thickness direction of the semiconductor chip 2. The second gate finger electrode 74 is preferably formed at an interval from the trench separation structure 20 and the plurality of trench structures 30 in plan view.

As illustrated in FIGS. 1 and 3, the boundary gate finger electrode 83 is drawn out from the gate pad electrode 72 to immediately above the boundary wiring 42. The boundary gate finger electrode 83 is formed in a band shape extending along the boundary wiring 42 such as to cover the plurality of gate via electrodes 82.

As illustrated in FIG. 7, the boundary gate finger electrode 83 is electrically connected to the boundary wiring 42 through the plurality of gate via electrodes 82. The boundary gate finger electrode 83 opposes the gate wiring 40 (boundary wiring 42) and the boundary well region 50 (second boundary well region 52) in the thickness direction of the semiconductor chip 2.

As illustrated in FIGS. 4 and 7, in the second direction Y, the boundary gate finger electrode 83 has a width smaller than the width of the boundary well region 50, and has a peripheral edge located closer to the boundary region 7 side than the peripheral edge of the boundary well region 50. Specifically, the boundary gate finger electrode 83 has a width smaller than the width of the boundary wiring 42, and has a peripheral edge located closer to the boundary region 7 side than the peripheral edge of the boundary wiring 42. In the present preferred embodiment, the boundary gate finger electrode 83 has a width smaller than the width of the boundary region 7, and has a peripheral edge located further inward than the peripheral edge of the boundary region 7.

As illustrated in FIG. 4, the boundary gate finger electrode 83 is disposed only immediately above the boundary region 7 in plan view, and is not disposed above each IGBT region 6. Specifically, the boundary gate finger electrode 83 is disposed above the boundary region 7 at an interval from the plurality of trench structures 30 in the first IGBT region 6A and the plurality of trench structures 30 in the second IGBT region 6B in plan view. The boundary gate finger electrode 83 is disposed above the boundary region 7 at an interval from the first trench separation structure 20A and the second trench separation structure 20B in plan view.

With reference to FIG. 1, the semiconductor device 1 includes an emitter electrode 75 disposed on the interlayer insulating film 60 at an interval from the gate wiring 40. The emitter electrode 75 is constituted of a conductive material different from the gate wiring 40. In the present preferred embodiment, the emitter electrode 75 is constituted of a metal film. The emitter electrode 75 may be referred to as an “emitter metal.” The emitter electrode 75 may include at least one among a Ti-based metal film, a W-based metal film, an Al-based metal film, and a Cu-based metal film. The emitter electrode 75 may have a laminated structure including the Ti-based metal film and the Al-based metal film.

As illustrated in FIGS. 6, 7, and 12A, the emitter electrode 75 is disposed on the interlayer insulating film 60 such as to cover the plurality of IGBT regions 6. The emitter electrode 75 collectively covers the plurality of via electrodes 70 and is electrically connected to the plurality of emitter regions 35 through the plurality of via electrodes 70. In the present preferred embodiment, the emitter electrode 75 has a portion covering the boundary wiring 42 of the gate wiring 40 with the interlayer insulating film 60 interposed therebetween. That is, the emitter electrode 75 has a portion opposing the gate wiring 40 (boundary wiring 42) and the boundary well region 50 in the thickness direction of the semiconductor chip 2.

As illustrated in FIGS. 1 and 2, in the present preferred embodiment, the emitter electrode 75 includes an emitter pad electrode 76 and an emitter finger electrode 77. The emitter pad electrode 76 covers the plurality of IGBT regions 6 and the boundary region 7.

As illustrated in FIG. 6, the emitter pad electrode 76 opposes the gate wiring 40 with the interlayer insulating film 60 interposed therebetween, and is electrically connected to the plurality of emitter regions 35 through the plurality of via electrodes 70. As illustrated in FIG. 12A, the emitter pad electrode 76 enters the first well opening 63 from above the interlayer insulating film 60. The emitter pad electrode 76 is electrically connected to the inner edge portion of the outer peripheral well region 56 in the first well opening 63.

As illustrated in FIGS. 1 and 2, the emitter finger electrode 77 is drawn out from the emitter pad electrode 76 to a region between the peripheral edge of the first principal surface 3 and the gate electrode 71, and extends in a band shape along the gate electrode 71. In the present preferred embodiment, the emitter finger electrode 77 is formed in a quadrangular annular shape surrounding the gate electrode 71 and the emitter pad electrode 76. As illustrated in FIG. 11A, the emitter finger electrode 77 enters the second well opening 64 from above the interlayer insulating film 60. The emitter finger electrode 77 is electrically connected to an outer edge portion in the second well opening 64.

As illustrated in FIGS. 1 and 4, in the present preferred embodiment, the emitter electrode 75 has a notched portion 84 extending in a band shape along the boundary gate finger electrode 83 in plan view. The notched portion 84 demarcates a slit 85 extending in a band shape along the boundary gate finger electrode 83 between the boundary gate finger electrode 83 and the notched portion 84. The slit 85 is formed immediately above the boundary well region 50 in plan view. The slit 85 is preferably formed immediately above the boundary region 7 in plan view.

As illustrated in FIG. 4, in the present preferred embodiment, the slit 85 is formed above the boundary region 7 at an interval from the plurality of trench structures 30 in the first IGBT region 6A and the plurality of trench structures 30 in the second IGBT region 6B. Also, the slit 85 is formed above the boundary region 7 at an interval from the first trench separation structure 20A and the second trench separation structure 20B in plan view. The slit 85 may oppose the boundary well region 50 (second boundary well region 52) in the thickness direction of the semiconductor chip 2.

As illustrated in FIGS. 6, 7, and 12A, the semiconductor device 1 includes a collector electrode 80 covering the second principal surface 4. The collector electrode 80 is electrically connected to the collector region 13 exposed from the second principal surface 4. The collector electrode 80 forms an ohmic contact with the collector region 13. The collector electrode 80 may cover the entire region of the second principal surface 4 such as to be continuous with the peripheral edge (first to fourth side surfaces 5A to 5D) of the semiconductor chip 2.

The collector electrode 80 may include at least one among a Ti film, an Ni film, a Pd film, an Au film, an Ag film, and an Al film. The collector electrode 80 may have a single film structure including a Ti film, an Ni film, an Au film, an Ag film, or an Al film. The collector electrode 80 may have a laminated structure in which at least two among a Ti film, an Ni film, a Pd film, an Au film, an Ag film, and an Al film are laminated in an arbitrary manner. The collector electrode 80 preferably includes a Ti film directly covering at least the second principal surface 4. The collector electrode 80 may have, for example, a laminated structure including a Ti film, an Ni film, a Pd film, and an Au film laminated in this order from the second principal surface 4 side.

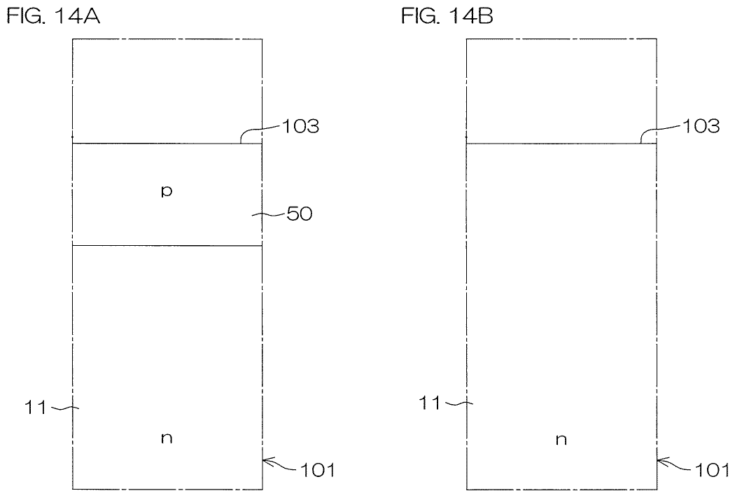

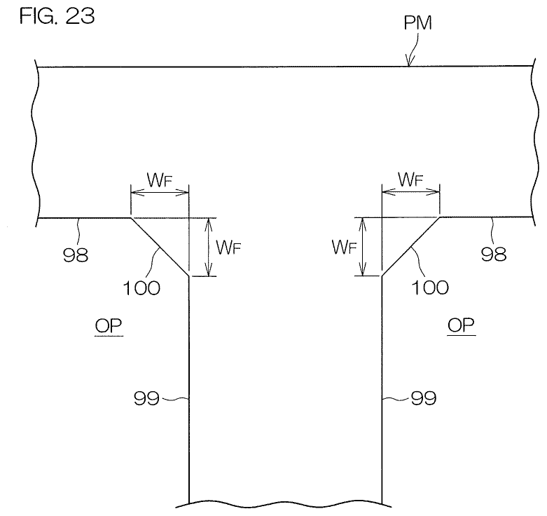

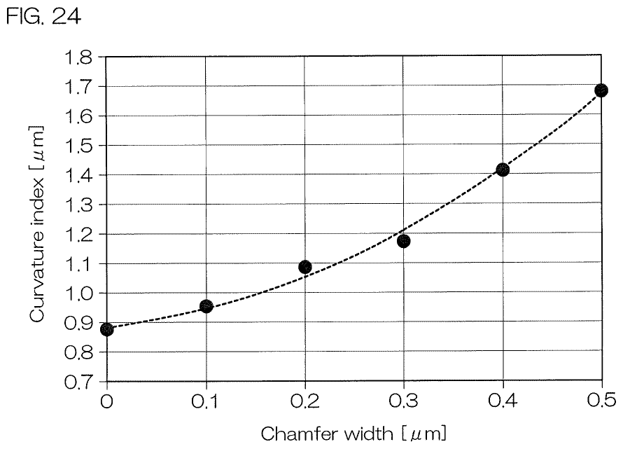

FIGS. 14A to 22A and FIGS. 14B to 22B are diagrams illustrating a part of a manufacturing process of the semiconductor device 1 in order of steps. FIG. 23 is a diagram for describing a patterning mask PM. FIGS. 14A to 22A are longitudinal sectional views of a portion corresponding to FIG. 8. FIGS. 14B to 22B are longitudinal sectional views of a portion corresponding to FIG. 9. In FIGS. 14A to 22A and FIGS. 14B to 22B, among the reference signs shown in FIGS. 8 and 9, only the reference signs of the configurations necessary for describing the manufacturing process of the semiconductor device 1 are shown, and the other reference signs are omitted.

As illustrated in FIGS. 14A and 14B, upon manufacturing of the semiconductor device 1, first, an n-type semiconductor wafer 101 is prepared. The semiconductor wafer 101 has a first wafer principal surface 103. The first wafer principal surface 103 of the semiconductor wafer 101 corresponds to the first principal surface 3 of the semiconductor chip 2.

Next, as illustrated in FIGS. 14A and 14B, the p-type boundary well region 50 is formed on the first wafer principal surface 103. The p-type outer peripheral well region 56 (see FIG. 11) may be formed simultaneously with the boundary well region 50.

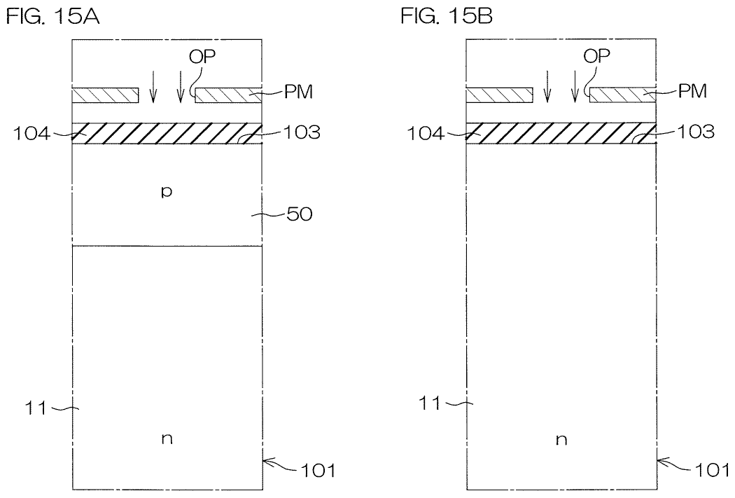

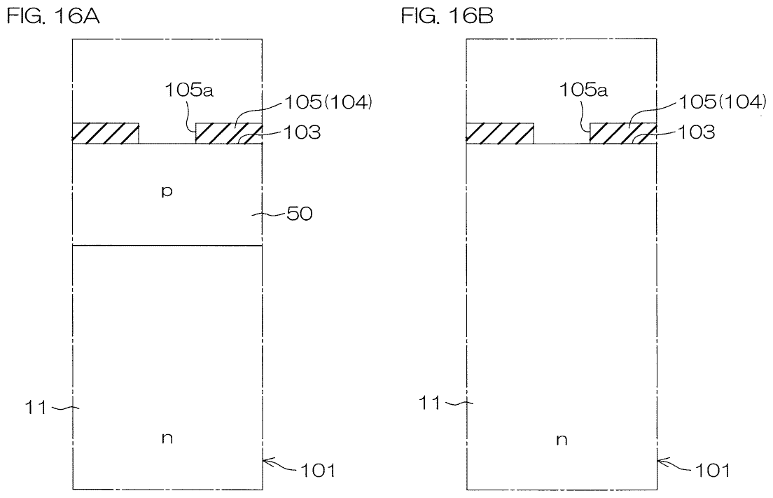

Next, as illustrated in FIGS. 15A, 15B, 16A, and 16B, the separation trench 21 and the gate trench 31 are formed on the first wafer principal surface 103. In this step, first, as illustrated in FIGS. 15A and 15B, a resist 104 is applied onto the first wafer principal surface 103 of the semiconductor wafer 101, and a patterning mask (virtual figure) PM is disposed on the resist 104. The patterning mask PM has a predetermined opening pattern OP.

As illustrated in FIG. 23, the opening pattern OP of the patterning mask PM includes a first rectilinear portion 98 and a second rectilinear portion 99 orthogonal to each other, and a chamfered portion 100 inclined at an angle of 45° with respect to the first rectilinear portion 98 and the second rectilinear portion 99. The chamfered portion 100 has a predetermined chamfer width W_{F}.

The rectilinear portion 98 corresponds to the first side 93 (see FIG. 13) of the corner portion (corner portion 92P of the T-shaped intersection portion 91P, corner portion 92Q of the L-shaped intersection portion 91Q). The rectilinear portion 99 corresponds to the second side 94 (see FIG. 13) of the corner portion (corner portion 92P, corner portion 92Q).

There is a correlation between the chamfer width W_{F} of the patterning mask PM and the curvature index CI (curvature index CI_{P}, curvature index CI_{Q}) of the corner portion (92P, 92Q) formed using the patterning mask PM. For example, the chamfer width W_{F}=0.4 μm corresponds to the curvature index CI=1.45 μm, the chamfer width W_{F}=0.5 μm corresponds to the curvature index CI=1.73 μm, and the chamfer width W_{F}=0.7 μm corresponds to the curvature index CI=2.44 μm.

By irradiating the resist 104 with light (for example, ultraviolet rays, etc.) through the patterning mask PM, the resist 104 is exposed, and a portion of the resist 104 exposed through the opening pattern OP is removed. As a result, as illustrated in FIGS. 16A and 16B, a second resist mask 105 having an opening 105a in the same pattern as the opening pattern OP of the patterning mask PM is formed. The opening 105a of the second resist mask 105 is an opening that respectively exposes regions where the separation trench 21 and the gate trench 31 are to be formed. After the resist 104 is removed, the patterning mask PM is retracted from above the first wafer principal surface 103 of the semiconductor wafer 101.

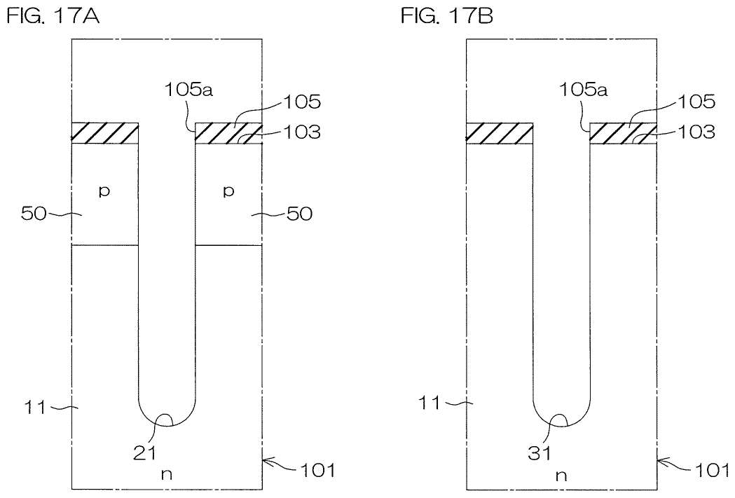

Next, as illustrated in FIGS. 17A and 17B, an unnecessary portion of the semiconductor wafer 101 is removed by an etching method through the second resist mask 105. The etching method may be a wet etching method. As a result, the separation trench 21 and the gate trench 31 are formed in the semiconductor wafer 101. Thereafter, the second resist mask 105 is removed.

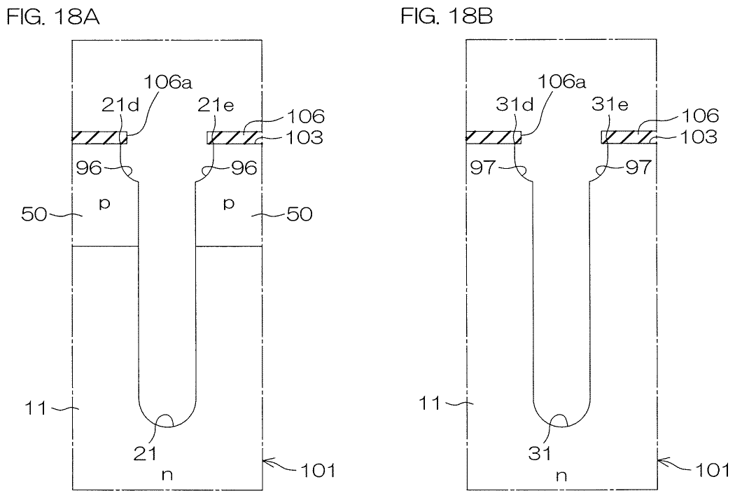

Next, as illustrated in FIGS. 18A and 18B, the first recess portion 96 and the second recess portion 97 are formed at the opening ends 21d and 21e of the separation trench 21 and the opening ends 31d and 31e of the gate trench 31, respectively. In this step, first, a third resist mask 106 having a predetermined pattern is formed on the first wafer principal surface 103. The third resist mask 106 has a plurality of openings 106a that respectively expose regions where the first recess portion 96 and the second recess portion 97 are to be formed.

Next, an unnecessary portion of the semiconductor wafer 101 is removed by an etching method through the third resist mask 106 (top corner etching (TCE) processing). The etching method may be a dry etching method. By the TCE processing, the first recess portion 96 and the second recess portion 97 are formed in the separation trench 21 and the gate trench 31, respectively. The TCE processing time is preferably 30 minutes or more. The processing time of the TCE processing is set such that the third width W₃ (see FIG. 8) of the first recess portion 96 of the separation trench 21 and the fourth width W₄ (see FIG. 10) of the gate trench 31 and the second recess portion 97 become sufficient widths. After the TCE processing is completed, the third resist mask 106 is removed.

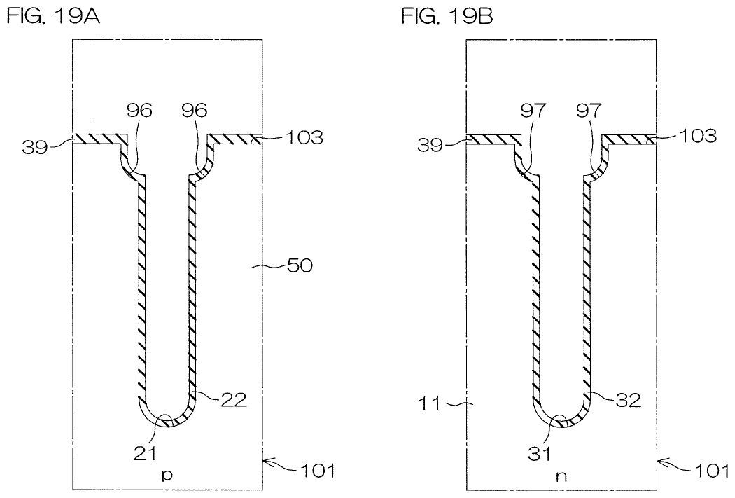

Next, as illustrated in FIGS. 19A and 19B, the p-type boundary well region 50 is diffused into the semiconductor wafer 101. The boundary well region 50 is diffused to a depth position covering the bottom wall of the separation trench 21.

Next, as illustrated in FIGS. 19A and 19B, the separation insulating film 22, the gate insulating film 32, and the principal surface insulating film 39 are formed on the first wafer principal surface 103. The separation insulating film 22, the gate insulating film 32, and the principal surface insulating film 39 may be formed by a chemical vapor deposition (CVD) method or an oxidation treatment method (for example, a thermal oxidation treatment method).

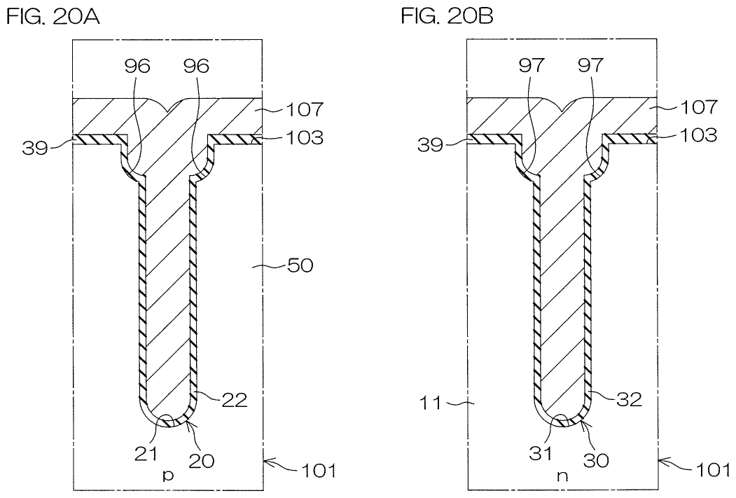

Next, as illustrated in FIGS. 19A, 19B, 20A, and 20B, the separation embedded electrode 23, the boundary wiring 42, and the gate embedded electrode 33 are formed. First, a base electrode layer 107 is deposited on the first wafer principal surface 103. The base electrode layer 107 contains conductive polysilicon. The base electrode layer 107 may be formed by a CVD method.

Next, as illustrated in FIGS. 20A and 20B, an unnecessary portion of the base electrode layer 107 is removed. In this step, first, a resist mask (not illustrated) having a predetermined pattern respectively covers regions where the boundary wiring 42 and the gate embedded electrode 33 are to be formed, and has an opening that exposes a region other than these regions. Next, the unnecessary portion of the base electrode layer 107 is removed by an etching method through the resist mask. The etching method may be a wet etching method. As a result, the boundary wiring 42 and the gate embedded electrode 33 are formed.

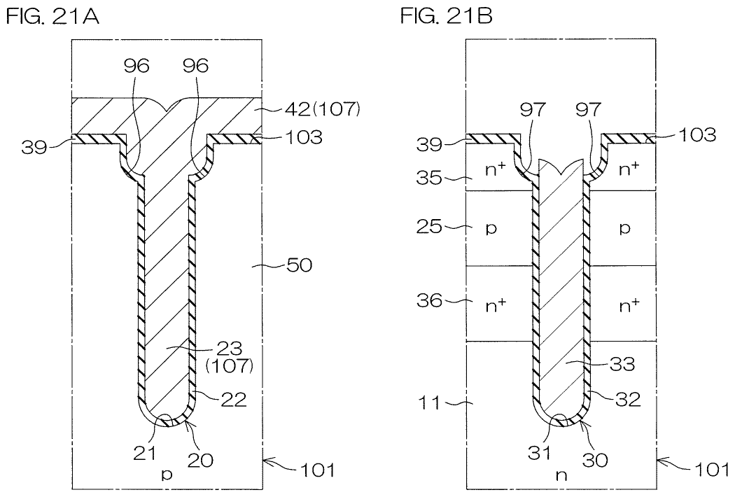

Next, as illustrated in FIGS. 21A and 21B, n-type impurities are introduced into the semiconductor wafer 101 through an ion introducing mask, thereby forming the plurality of carrier storage regions 36 in a surface layer portion of the semiconductor wafer 101. Thereafter, the ion introducing mask is removed. Next, p-type impurities are introduced into the first wafer principal surface 103 of the semiconductor wafer 101 through the ion introducing mask. As a result, the plurality of base regions 25 are formed in the surface layer portion of the semiconductor wafer 101. Thereafter, the ion introducing mask is removed. Next, n-type impurities are introduced into the first wafer principal surface 103 of the semiconductor wafer 101 through the ion introducing mask. As a result, the plurality of emitter regions 35 are formed in the surface layer portion of the semiconductor wafer 101. Thereafter, the ion introducing mask is removed.

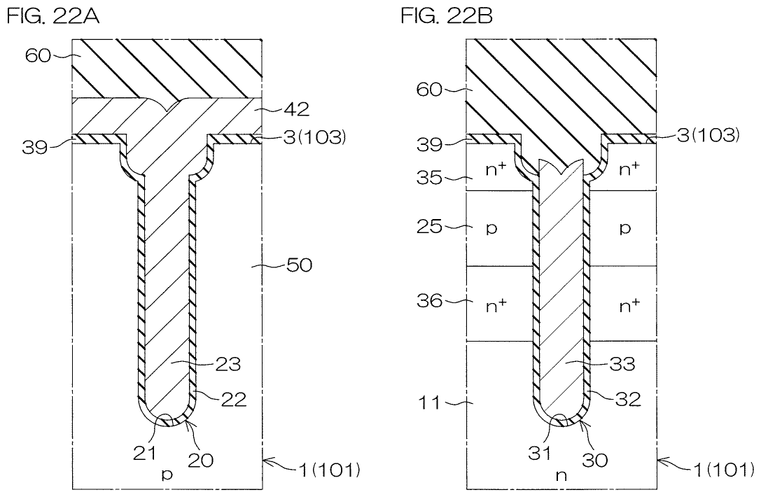

Next, as illustrated in FIGS. 22A and 22B, the interlayer insulating film 60 is formed on the first wafer principal surface 103. Thereafter, the gate electrode 71, the emitter electrode 75, etc., are formed on the first wafer principal surface 103. The semiconductor device 1 is obtained by the process including the above steps.

Next, a first breakdown test will be described. The following Examples 1 and 2 and Reference Examples 1 to 4 were adopted as the semiconductor device 1 to be tested in the first breakdown test.

### Examples 1 and 2

The semiconductor device 1 illustrated in FIGS. 1 to 3 was manufactured by the manufacturing process illustrated in FIGS. 14A to 22A and FIGS. 14B to 22B. In Examples 1 and 2, the chamfer width W_{F} of the patterning mask PM used for manufacturing the corner portion 92P of the T-shaped intersection portion 91P (see FIG. 5) and manufacturing the corner portion 92Q of the L-shaped intersection portion 91Q (see FIG. 12B) was set to 0.4 μm (Example 1) and 0.5 μm (Example 2). When the chamfer width W_{F} is 0.4 μm, the curvature index CI (see FIG. 13) is 1.45 μm. When the chamfer width W_{F} is 0.5 μm, the curvature index CI is 1.73 μm.

In Examples 1 and 2, the first width W₁ (see FIG. 8) of the separation trench 21 is 1.0 μm, and the second width W₂ (see FIG. 10) of the gate trench 31 is 1.0 μm. The first recess portion 96 (see FIG. 8) is not formed at the opening ends 21d and 21e of the separation trench 21. The second recess portion 97 (see FIG. 10) is not formed at the opening ends 31d and 31e of the gate trench 31.

### Reference Examples 1 to 4

In Reference Examples 1 to 4, the chamfer width W_{F} of the patterning mask PM used for manufacturing the semiconductor device 1 was set to 0.0 μm (Reference Example 1), 0.1 μm (Reference Example 2), 0.2 μm (Reference Example 3), and 0.3 μm (Reference Example 4). When the chamfer width W_{F} is 0.0 μm, the patterning mask PM is not chamfered. When the chamfer width W_{F} is 0.0 μm, the curvature index CI (see FIG. 13) is 0.76 μm. That is, even if the patterning mask PM is not chamfered, the corner portion (corner portion 92P, corner portion 92Q) of the T-shaped intersection portion 91P and the L-shaped intersection portion 91Q forms a round shape (see FIGS. 5 and 12B). When the patterning mask PM is chamfered, the curvature of the corner portion (corner portion 92P, corner portion 92Q) becomes gentle. When the chamfer width W_{F} is 0.1 μm, the curvature index CI is 0.86 μm. When the chamfer width W_{F} is 0.2 μm, the curvature index CI is 1.02 μm. When the chamfer width W_{F} is 0.3 μm, the curvature index CI is 1.20 μm.

From the above, the graph of FIG. 23 is obtained as the relationship between the chamfer width W_{F} of the patterning mask PM and the curvature index CI. As can be seen from FIG. 23, by increasing the chamfer width W_{F} of the patterning mask PM, the curvature index CI also increases quadratic-functionally with the increase. That is, by appropriately adjusting the chamfer width W_{F} of the patterning mask PM, the curvature index CI of the corner portion 92P of the T-shaped intersection portion 91P and the corner portion 92Q of the L-shaped intersection portion 91Q can be freely changed.

Next, Examples 1 and 2 and Reference Examples 1 to 4 were subjected to, as the first breakdown test, an electrostatic breakdown resistance test (ESD test) for measuring electrostatic breakdown resistance (ESD resistance) and a time-zero dielectric breakdown resistance test (TZDB test) for measuring time-zero dielectric breakdown resistance.

In the electrostatic breakdown resistance test (ESD test), three each of samples corresponding to each of Examples 1 and 2 and Reference Examples 1 to 4 were prepared, and a breakdown voltage BV was measured for each sample. The breakdown voltage is a voltage that causes the semiconductor device 1 to break down, and is measured by increasing a collector voltage from 0 V to a voltage that causes the semiconductor device 1 to break down in a state where an emitter voltage is 0 V and a gate voltage is 0 V. In the present preferred embodiment, the electrostatic breakdown resistance test is a human body model (HBM) test. The electrostatic breakdown resistance of the semiconductor device 1 when a charged human body comes into contact with the semiconductor device 1 as a sample of the test is measured.

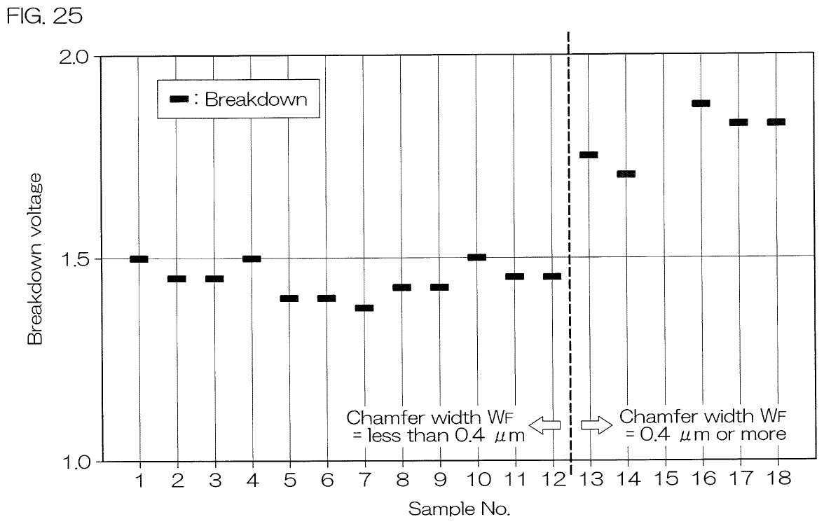

The test results of the electrostatic breakdown resistance test are shown in FIG. 25. In FIG. 25, a value of the breakdown voltage is expressed as a relative value when a reference voltage value is 1. In FIG. 25, samples 1 to 3 correspond to Reference Example 1, samples 4 to 6 correspond to Reference Example 2, samples 7 to 9 correspond to Reference Example 3, and samples 10 to 12 correspond to Reference Example 4. In FIG. 25, samples 13 to 15 correspond to Example 1, and samples 16 to 18 correspond to Example 2.

From the test results shown in FIG. 25, it is found that Examples 1 and 2 have higher breakdown voltage values than Reference Examples 1 to 4. That is, it is found that the electrostatic breakdown resistance is high in Examples 1 and 2. As a result, it is found that the electrostatic breakdown resistance of the semiconductor device 1 increases when the curvature index CI (see FIG. 13) is 1.5 μm or more.

In the time-zero dielectric breakdown resistance test (TZDB test), the semiconductor devices 1 disposed at various places in the plane of a circular wafer W were measured. An applied voltage (V_{ge}) at the time of measurement is 80 V. The semiconductors to be measured are Examples 1 and 2 and Reference Examples 1 to 4.

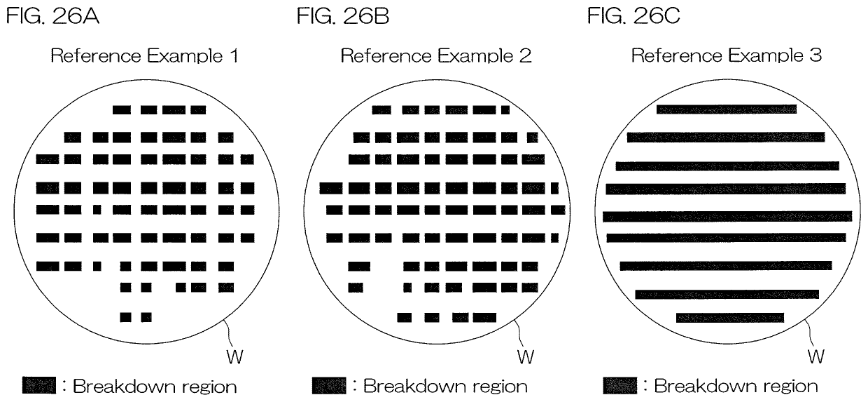

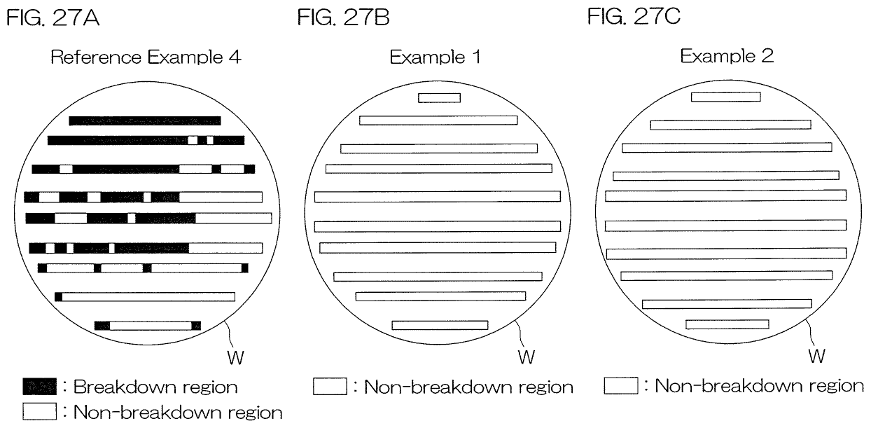

The test results of the time-zero dielectric breakdown resistance test are shown in FIGS. 26A to 26C and FIGS. 27A to 27C. In FIGS. 26A to 26C and FIGS. 27A to 27C, a portion of the wafer W where the chip through which a leak current larger than a reference value flows exists (breakdown region) is indicated by a solid quadrangle, and a portion of the wafer where the chip through which a leak current smaller than the reference value flows exists (non-breakdown region) is indicated by an open quadrangle. In the chip present in the portion indicated by the solid quadrangle, it is considered that the semiconductor device has caused the dielectric breakdown in the time-zero dielectric breakdown resistance test.

From the test results shown in FIGS. 26A and 26B and FIGS. 27A to 27C, it is found that Examples 1 and 2 have high dielectric breakdown resistance. As a result, it is found that the dielectric breakdown resistance increases when the curvature index CI of the semiconductor device 1 is 1.5 μm or more.

Next, a second breakdown test will be described. The following Examples 3 and 4 and Reference Example 5 were adopted as the semiconductor device 1 to be tested in the second breakdown test.

### Examples 3 and 4

The semiconductor device 1 illustrated in FIGS. 1 to 3 was manufactured by the manufacturing process illustrated in FIGS. 14A to 22A and FIGS. 14B to 22B. In Examples 1 and 2, the processing time of the TCE processing was 30 seconds (Example 3) and 45 seconds (Example 4), respectively. When the processing time of the TCE processing is 30 seconds, the third width W₃ (see FIG. 8) of the first recess portion 96 and the fourth width W₄ (see FIG. 10) of the second recess portion 97 are 1368 Å.

At this time, the third depth D₃ (see FIG. 8) and the fourth depth D₄ (see FIG. 10) are 1838 Å. When the processing time of the TCE processing is 45 seconds, the third width W₃ and the fourth width W₄ are 2176 Å. At this time, the third depth D₃ and the fourth depth D₄ are 2849 Å.

From the above, the graph of FIG. 28 is obtained as the relationship between the processing time of the TCE processing and the side etching amount of the trench. From FIG. 28, it is found that by increasing the processing time of the TCE processing, the side etching amount and the depth of the recess portion at the trench opening end also increase proportionally with the increase. That is, the third width W₃ and the third depth D₃ of the first recess portion 96 and the fourth width W₄ and the fourth depth D₄ of the second recess portion 97 can be freely changed by appropriately adjusting the processing time of the TCE processing.

In Examples 3 and 4, the first width W₁ (see FIG. 8) of the separation trench 21 is 1.0 μm, and the second width W₂ (see FIG. 10) of the gate trench 31 is 1.0 μm. The pitch P (see FIG. 6) is 15 μm. The width W₅ (see FIG. 4) of the mesa portion 90 is 10 μm. The curvature index CI (see FIG. 13) of the corner portion (corner portion 92P, corner portion 92Q) is 0.76 μm (corresponding to a chamfer width W_{F}=0.0 μm).

### Reference Example 5

In Reference Example 5, each processing time of the TCE processing was set to 15 seconds. When the processing time of the TCE processing is 15 seconds, the third width W₃ (see FIG. 8) of the first recess portion 96 and the fourth width W₄ (see FIG. 10) of the second recess portion 97 are 532 Å. At this time, the third depth D₃ (see FIG. 8) and the fourth depth D₄ (see FIG. 10) are 828 Å.

Next, as the second breakdown test, the time-zero dielectric breakdown resistance test (TZDB test) for measuring the time-zero dielectric breakdown resistance was performed on Examples 3 and 4 and Reference Example 5. The applied voltage (V_{ge}) was started at 78 V and gradually increased. In Reference Example 5, breakdown started when the applied voltage V_{ge} was 80 V, and therefore measurement was not performed at a voltage higher than that.

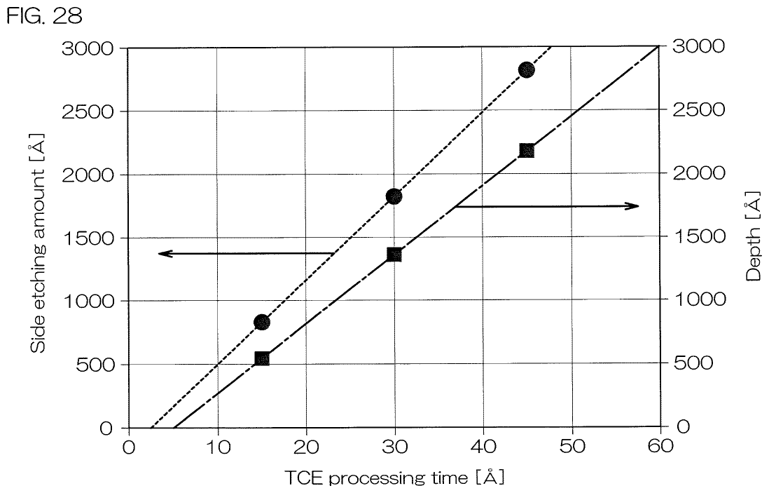

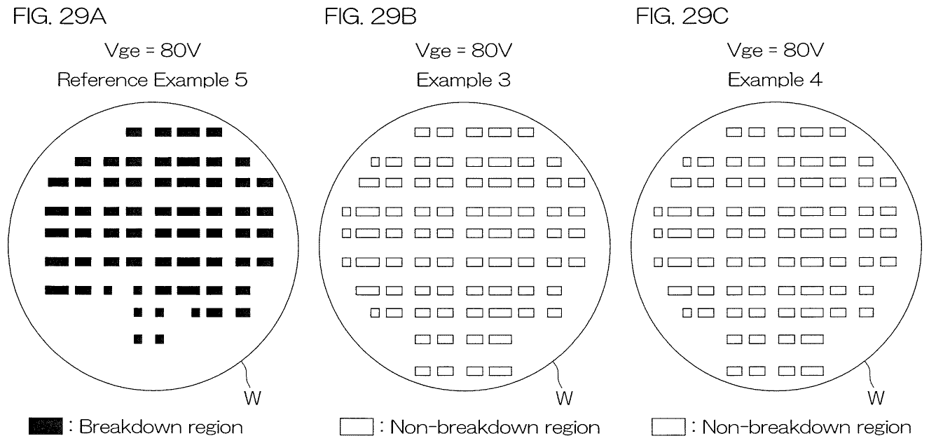

The test results of the time-zero dielectric breakdown resistance test (TZDB test) are shown in FIGS. 29A to 29C, 30A, 30B, 31A, and 31B.

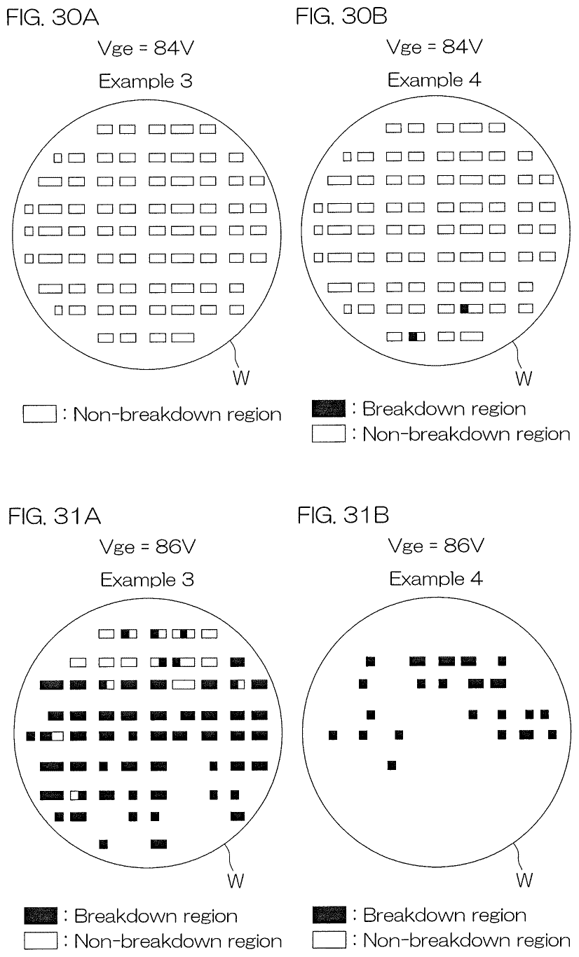

FIGS. 29A to 29C show test results when the applied voltage V_{ge} is 80 V. FIGS. 30A to 30C show test results when the applied voltage V_{ge} is 84 V. FIGS. 31A to 31C show test results when the applied voltage V_{ge} is 86 V.

In FIGS. 29A to 29C, 30A, 30B, 31A, and 31B, a portion of the wafer W where the chip through which a leak current larger than a reference value flows exists (breakdown region) is indicated by a solid quadrangle, and a portion of the wafer where the chip through which a leak current smaller than the reference value flows exists (non-breakdown region) is indicated by an open quadrangle. In the chip present in the portion indicated by the solid quadrangle, it is considered that the semiconductor device has caused the dielectric breakdown in the time-zero dielectric breakdown resistance test.

From the test results shown in FIGS. 29 to 31, it is found that Examples 3 and 4 have high dielectric breakdown resistance. As a result, it is found that the dielectric breakdown resistance is high when the third width W₃ (see FIG. 8) and the fourth width W₄ (see FIG. 10) are 1350 Å or more.

The IGBT structure Tr includes a large number of T-shaped intersection portions 91P. In the T-shaped intersection portion 91P, the electric field tends to concentrate. As a result, the semiconductor chip 2 may be broken with the T-shaped intersection portion 91P as a starting point. Therefore, the semiconductor device 1 is required to have a high electrostatic breakdown resistance (ESD resistance).

In general, the electrostatic breakdown resistance tends to increase as the chip size of the semiconductor chip 2 increases or as the gate capacitance increases. However, a high electrostatic breakdown resistance is required for the semiconductor device 1 regardless of the chip size and the gate capacitance of the semiconductor chip 2. Also, the semiconductor device 1 is required not only to have a high electrostatic breakdown resistance but also to have a high dielectric breakdown resistance.

According to the present preferred embodiment, the curvature index CI_{P} of the corner portion 92P of the T-shaped intersection portion 91P is 1.5 μm or more. Therefore, it is possible to alleviate the occurrence of electric field concentration at the corner portion 92P of the T-shaped intersection portion 91P, and it is possible to suppress current concentration at the corner portion 92P of the T-shaped intersection portion 91P. This makes it possible to suppress the occurrence of breakdown at the T-shaped intersection portion 91P.

Also, the curvature index CI_{P} of the corner portion 92P of the T-shaped intersection portion 91P is 2.4 μm or less. Therefore, the embeddability of the separation embedded electrode 23 in the separation trench 21 and the embeddability of the gate embedded electrode 33 in the gate trench 31 are not impaired. That is, it is possible to suppress the occurrence of breakdown at the T-shaped intersection portion 91P without impairing the embeddability of the embedded electrodes 23 and 33.

Also, the curvature index CI_{Q} of the corner portion 92Q of the L-shaped intersection portion 91Q is 1.5 μm or more. Therefore, it is possible to alleviate the occurrence of electric field concentration at the corner portion 92Q of the L-shaped intersection portion 91Q. Therefore, it is possible to suppress current concentration at the corner portion 92Q of the L-shaped intersection portion 91Q. This makes it possible to suppress the occurrence of breakdown at the L-shaped intersection portion 91Q.

The curvature index CI_{Q} of the corner portion 92Q of the L-shaped intersection portion 91Q is 2.4 μm or less. Therefore, the embeddability of the separation embedded electrode 23 in the separation trench 21 is not impaired. That is, it is possible to suppress the occurrence of breakdown at the L-shaped intersection portion 91Q without impairing the embeddability of the separation embedded electrode 23.

Therefore, the electrostatic breakdown resistance and the dielectric breakdown resistance of the semiconductor device 1 can be improved. This makes it possible to avoid thickening of the gate insulating film 32, the principal surface insulating film 39, and the interlayer insulating film 60 as a countermeasure for dielectric breakdown. As a result, the gate capacitance of the semiconductor device 1 can be reduced.

Also, according to the present preferred embodiment, the first recess portion 96 is formed at the opening ends 21d and 21e of the separation trench 21. Since the third width W₃ of the first recess portion 96 is 1350 Å or more, it is possible to alleviate the occurrence of electric field concentration at the opening ends 21d and 21e of the separation trench 21. Therefore, it is possible to suppress current concentration at the opening ends 21d and 21e of the separation trench 21. This makes it possible to suppress the occurrence of breakdown at the separation trench 21.

Also, since the third width W₃ of the first recess portion 96 is 2000 Å or less, the function of the separation trench 21 is not adversely affected. That is, it is possible to suppress the occurrence of breakdown at the separation trench 21 without adversely affecting the function of the separation trench 21.

Also, the second recess portion 97 is formed at the opening ends 31d and 31e of the gate trench 31. Since the fourth width W₄ of the second recess portion 97 is 1350 Å or more, it is possible to alleviate the occurrence of electric field concentration at the opening ends 31d and 31e of the gate trench 31. Therefore, it is possible to suppress current concentration at the opening ends 31d and 31e of the gate trench 31. This makes it possible to suppress the occurrence of breakdown at the opening ends 31d and 31e of the gate trench 31.

Also, since the fourth width W₄ of the second recess portion 97 is 2000 Å or less, the function of the gate trench 31 is not adversely affected. That is, it is possible to suppress the occurrence of breakdown at the gate trench 31 without adversely affecting the function of the gate trench 31.

Therefore, the electrostatic breakdown resistance and the dielectric breakdown resistance of the semiconductor device 1 can be further improved.

A description has been given of the preferred embodiment of the present disclosure, and the semiconductor device 1 of the present disclosure can also be implemented in other modes.

For example, in the above-described preferred embodiment, the semiconductor device 1 is an IGBT discrete on which an IGBT is mounted alone as a functional element, but may be a reverse-conducting insulated gate bipolar transistor (RC-IGBT) on which an IGBT and a diode are mounted together.

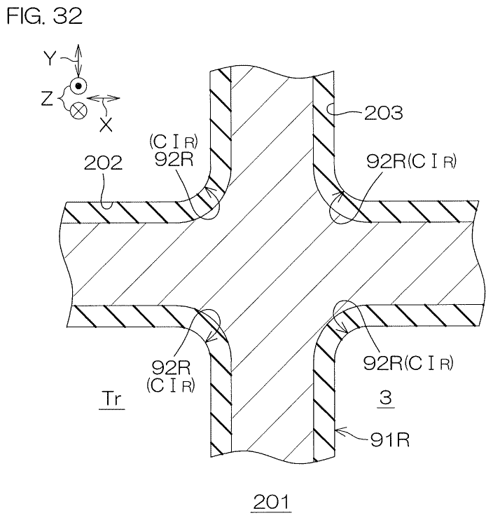

Also, as in the semiconductor device 201 illustrated in FIG. 32, the IGBT structure Tr may include a cross-shaped intersection portion 91R where two trenches 202 and 203 intersect in a cross shape as an intersection portion. The cross-shaped intersection portion 91R has four corner portions 92R. A curvature index CIR of each corner portion 92R may be 1.5 μm or more and 2.4 μm or less.

In each of the preferred embodiments described above, a structure with which the conductivity types of the respective semiconductor portions are inverted may be adopted. That is, a p-type portion may be formed as an n-type and an n-type portion may be formed as a p-type.

The following features can be extracted from the present description and the drawings.

### [Appendix 1-1]

A semiconductor device (1, 201) including:
a semiconductor chip (2) having a first principal surface (3) and a second principal surface (4) opposite to the first principal surface (3), and
a trench-type IGBT structure (Tr) formed on the first principal surface (3) of the semiconductor chip (2),
wherein the IGBT structure (Tr) includes
a trench (21, 31) formed in the first principal surface (3) of the semiconductor chip (2) and extending in a plurality of directions,
an insulating film (22, 32) formed on a side surface (21a, 21b, 31a, 31b) of the trench (21, 31),
an embedded conductor (23, 33) embedded inside the trench (21, 31) through the insulating film (22, 32), and
an intersection portion (91P, 91Q, 91R) formed by the trenches (21, 31) extending in the plurality of directions, and
a curvature index (CI_{P}, CI_{Q}) of a corner portion (92P, 92Q) of the intersection portion (91P, 91Q, 91R) is 1.5 μm or more.

According to this configuration, since the curvature index (CI_{P}, CI_{Q}) of the corner portion (92P, 92Q) of the intersection portion (91P, 91Q, 91R) of the trench (21, 31) is 1.5 μm or more, it is possible to alleviate the occurrence of electric field concentration at the corner portion (92P, 92Q) of the trench (21, 31). Therefore, it is possible to suppress current concentration at the corner portion (92P, 92Q) of the trench (21, 31). This makes it possible to suppress the occurrence of breakdown at the trench (21, 31). Therefore, dielectric breakdown resistance can be improved.

### [Appendix 1-2]

The semiconductor device (1, 201) according to Appendix 1-1, wherein a chamfer width (W_{F}) of a virtual figure formed by an extension line (E1, E2) of two sides forming the corner portion (92P, 92Q) of the intersection portion (91P, 91Q, 91R) is 0.4 μm or more.

### [Appendix 1-3]

The semiconductor device (1, 201) according to Appendix 1-1 or Appendix 1-2, wherein the curvature index (CI_{P}, CI_{Q}) of the corner portion (92P, 92Q) of the intersection portion (91P, 91Q, 91R) is 2.4 μm or less.

### [Appendix 1-4]

The semiconductor device (1, 201) according to any one of Appendix 1-1 to Appendix 1-3, wherein a ratio (CI/W₁, CI/W₂) of the curvature index (CI_{P}, CI_{Q}) of the corner portion (92P, 92Q) of the intersection portion (91P, 91Q, 91R) to a width (W₁, W₂) of the trench (21, 31) is 1.5 or more.

### [Appendix 1-5]

The semiconductor device (1, 201) according to Appendix 1-4, wherein the ratio (CI/W₁, CI/W₂) of the curvature index (CI_{P}, CI_{Q}) of the corner portion (92P, 92Q) of the intersection portion (91P, 91Q, 91R) to the width (W₁, W₂) of the trench (21, 31) is 2.4 or less.

### [Appendix 1-6]

The semiconductor device (1, 201) according to any one of Appendix 1-1 to Appendix 1-5, wherein the trenches (21, 31) extending in the plurality of directions include a first trench (21) and a plurality of second trenches (31) that intersect the first trench (21) at the intersection portion (91P, 91Q, 91R), the plurality of second trenches (31) being aligned in a stripe shape at intervals from each other, and
a ratio (CI_{P}/P, CI_{Q}/P) of the curvature index (CI_{P}, CI_{Q}) of the corner portion (92P, 92Q) of the intersection portion (91P, 91Q, 91R) to a pitch (P) of the plurality of second trenches (31) is 0.1 or more.

### [Appendix 1-7]

The semiconductor device (1, 201) according to Appendix 1-6, wherein the ratio (CI_{P}/P, CI_{Q}/P) of the curvature index (CI_{P}, CI_{Q}) of the corner portion (92P, 92Q) of the intersection portion (91P, 91Q, 91R) to the pitch (P) of the plurality of second trenches (31) is 0.16 or less.

### [Appendix 1-8]

The semiconductor device (1, 201) according to any one of Appendix 1-1 to Appendix 1-7, wherein the trenches (21, 31) extending in the plurality of directions include a first trench (21) and a plurality of second trenches (31) that intersect the first trench (21) at the intersection portion (91P, 91Q, 91R), the plurality of second trenches (31) being aligned in a stripe shape at intervals from each other, and
a ratio (CI_{P}/W₅, CI_{Q}/W₅) of the curvature index (CI_{P}, CI_{Q}) of the corner portion (92P, 92Q) of the intersection portion (91P, 91Q, 91R) to a width (W₅) of a mesa portion (90) demarcated between the plurality of second trenches (31) is 0.11 or more.

### [Appendix 1-9]

The semiconductor device (1, 201) according to Appendix 1-8, wherein the ratio (CI_{P}/W₅, CI_{Q}/W₅) of the curvature index (CI_{P}, CI_{Q}) of the corner portion (92P, 92Q) of the intersection portion (91P, 91Q, 91R) to the width (W₅) of the mesa portion (90) is 0.17 or less.

### [Appendix 1-10]

The semiconductor device (1, 201) according to any one of Appendix 1-1 to Appendix 1-9, wherein the embedded conductor (23, 33) includes a gate embedded electrode (33) that controls a channel of the IGBT structure (Tr), and
includes a drawer portion (40) integrally drawn out from the gate embedded electrode (33) onto the first principal surface (3) and covering the corner portion (92P, 92Q) of the intersection portion (91P, 91Q, 91R).

### [Appendix 1-11]

The semiconductor device (1, 201) according to any one of Appendix 1-1 to Appendix 1-3, wherein the trenches (21, 31) extending in the plurality of directions include a plurality of gate trenches (31) aligned in a stripe shape at intervals in a first direction, each of the plurality of gate trenches (31) extending in a second direction, and a connection trench (21) extending in the first direction, connecting end portions in the second direction of the plurality of gate trenches (31) to each other, and forming the T-shaped intersection portion (91P, 91Q, 91R) at a connection portion with each of the gate trenches (31), and
the embedded conductor (23, 33) is integrally embedded in the gate trench (31) and the connection trench (21), and
includes a drawer portion (40) drawn out from the embedded conductor (23, 33) onto the first principal surface (3) and covering the corner portion (92P, 92Q) of the intersection portion (91P, 91Q, 91R).

### [Appendix 1-12]

The semiconductor device (1, 201) according to Appendix 1-11, wherein widths of the gate trench (31) and the connection trench (21) are equal, and
a ratio of the curvature index (CI_{P}, CI_{Q}) of the corner portion (92P, 92Q) of the intersection portion (91P, 91Q, 91R) to the widths of the gate trench (31) and the connection trench (21) is 1.5 or more and 2.4 or less.

### [Appendix 1-13]

The semiconductor device (1, 201) according to Appendix 1-11 or Appendix 1-12, wherein a ratio of the curvature index (CI_{P}, CI_{Q}) of the corner portion (92P, 92Q) of the intersection portion (91P, 91Q, 91R) to a pitch (P) of the plurality of gate trenches (31) is 0.1 or more and 0.16 or less.

### [Appendix 1-14]

The semiconductor device (1, 201) according to any one of Appendix 1-11 to Appendix 1-13, wherein a ratio of the curvature index (CI_{P}, CI_{Q}) of the corner portion (92P, 92Q) of the intersection portion (91P, 91Q, 91R) to a width of a mesa portion (90) demarcated between the plurality of gate trenches (31) is 0.11 or more and 0.17 or less.

### [Appendix 1-15]

The semiconductor device (1, 201) according to any one of Appendix 1-11 to Appendix 1-14, further including a gate finger electrode (83) extending in the second direction in a region on the connection trench (21) and connected to the drawer portion (40).

### [Appendix 1-16]

The semiconductor device (1, 201) according to any one of Appendix 1-1 to Appendix 1-15, wherein a size of the semiconductor chip (2) is 0.5 mm square or more and 20 mm square or less.

### [Appendix 1-17]

The semiconductor device (1, 201) according to any one of Appendix 1-1 to Appendix 1-16, wherein a gate capacitance value of the semiconductor chip (2) is 300 pF or less.

### [Appendix 1-18]

The semiconductor device (1, 201) according to any one of Appendix 1-1 to Appendix 1-9, wherein the intersection portion (91P, 91Q, 91R) includes a T-shaped intersection portion (91P) where the trenches (21, 31) extending in the plurality of directions intersect in a T-shape.

### [Appendix 1-19]

The semiconductor device (1, 201) according to any one of Appendix 1-1 to Appendix 1-10, wherein the intersection portion (91P, 91Q, 91R) includes an L-shaped intersection portion (91Q) where the trenches (21, 31) extending in the plurality of directions intersect in an L-shape.

### [Appendix 1-20]

The semiconductor device (1, 201) according to any one of Appendix 1-1 to Appendix 1-10, wherein the intersection portion (91P, 91Q, 91R) includes a cross-shaped intersection portion (91R) where the trenches (21, 31) extending in the plurality of directions intersect in a cross-shape.

### [Appendix 2-1]

A semiconductor device (1, 201) including:
a semiconductor chip (2) having a first principal surface (3) and a second principal surface (4) opposite to the first principal surface (3), and
a trench-type IGBT structure (Tr) formed on the first principal surface (3) of the semiconductor chip (2),
wherein the IGBT structure (Tr) includes
a trench (21, 31) formed in the first principal surface (3) of the semiconductor chip (2),
an insulating film (22, 32) formed on a side surface (21a, 21b, 31a, 31b) of the trench (21, 31), and
an embedded conductor (23, 33) embedded inside the trench (21, 31) through the insulating film (22, 32),
a recess portion (96, 97) recessed toward the side surface (21a, 21b, 31a, 31b) side of the trench (21, 31) is formed at an opening end (21d, 21e, 31d, 31e) of the trench (21, 31), and
a width (W₃, W₄) of the recess portion (96, 97) is 1350 Å or more.

According to this configuration, the recess portion (96, 97) is formed at the opening end (21d, 21e, 31d, 31e) of the trench (21, 31). Since the width (W₃, W₄) of the recess portion (96, 97) is 1350 Å or more, it is possible to alleviate the occurrence of electric field concentration at the opening end (21d, 21e, 31d, 31e) of the trench (21, 31). Therefore, it is possible to suppress current concentration at the opening end (21d, 21e, 31d, 31e) of the trench (21, 31). This makes it possible to suppress the occurrence of breakdown at the trench (21, 31). Therefore, dielectric breakdown resistance can be improved.

### [Appendix 2-2]

The semiconductor device (1, 201) according to Appendix 2-1, wherein a depth (D₃, D₄) of the recess portion (96, 97) is 1850 Å or more.

### [Appendix 2-3]

The semiconductor device (1, 201) according to Appendix 2-1 or Appendix 2-2, wherein the width (W₃, W₄) of the recess portion (96, 97) is 2000 Å or less.

### [Appendix 2-4]

The semiconductor device (1, 201) according to any one of Appendix 2-1 to Appendix 2-3, wherein a ratio (W₃/W₁, W₄/W₂) of the width (W₃, W₄) of the recess portion (96, 97) to a width (W₁, W₂) of the trench (21, 31) is 0.14 or more.

### [Appendix 2-5]

The semiconductor device (1, 201) according to Appendix 2-4, wherein the ratio (W₃/W₁, W₄/W₂) of the width (W₃, W₄) of the recess portion (96, 97) to the width (W₁, W₂) of the trench (21, 31) is 0.2 or less.

### [Appendix 2-6]

The semiconductor device (1, 201) according to any one of Appendix 2-1 to Appendix 2-5, wherein the plurality of trenches (31) are aligned in a stripe shape at intervals from each other, and
a ratio (W₄/P) of the width (W₄) of the recess portion (97) to a pitch (P) of the plurality of trenches (31) is 0.009 or more.

### [Appendix 2-7]

The semiconductor device (1, 201) according to Appendix 2-6, wherein the ratio (W₄/P) of the width (W₄) of the recess portion (97) to the pitch (P) of the plurality of trenches (31) is 0.0133 or less.

### [Appendix 2-8]

The semiconductor device (1, 201) according to any one of Appendix 2-1 to Appendix 2-7, wherein the plurality of trenches (31) are aligned in a stripe shape at intervals from each other, and a ratio (W₄/W₅) of the width (W₄) of the recess portion (97) to a width (W₅) of a mesa portion (90) demarcated between the plurality of trenches (31) is 0.011 or more.

### [Appendix 2-9]

The semiconductor device (1, 201) according to Appendix 2-8, wherein the ratio (W₄/W₅) of the width (W₄) of the recess portion (97) to the width (W₅) of the mesa portion (90) is 0.017 or less.

### [Appendix 2-10]

The semiconductor device (1, 201) according to any one of Appendix 2-1 to Appendix 2-9, wherein the embedded conductor (23, 33) includes a gate embedded electrode (33) that controls a channel of the IGBT structure (Tr), and includes a drawer portion (40) integrally drawn out from the gate embedded electrode (33) onto the first principal surface (3) and covering the recess portion (96, 97).

### [Appendix 2-11]

The semiconductor device (1, 201) according to any one of Appendix 2-1 to Appendix 2-3, wherein the trench (21, 31) is formed by a plurality of gate trenches (31) aligned in a stripe shape at intervals in a first direction, each of the plurality of gate trenches (31) extending in a second direction, and a connection trench (21) extending in the first direction, connecting end portions in the second direction of the plurality of gate trenches (31) to each other, and forming a T-shaped intersection portion (91P, 91Q, 91R) at a connection portion with each of the gate trenches (31),
the recess portion (96, 97) is formed at the intersection portion (91P, 91Q, 91R) of the trench (21, 31), and
the embedded conductor (23, 33) is integrally embedded in the gate trench (31) and the connection trench (21), and
includes a drawer portion (40) drawn out from the embedded conductor (23, 33) onto the first principal surface (3) and covering the recess portion (96, 97) of the intersection portion (91P, 91Q, 91R).

### [Appendix 2-12]

The semiconductor device (1, 201) according to Appendix 2-11, wherein widths of the gate trench (31) and the connection trench (21) are equal, and
a ratio of a width of the recess portion (96, 97) to the widths of the gate trench (31) and the connection trench (21) is 0.14 or more and 0.2 or less.

### [Appendix 2-13]

The semiconductor device (1, 201) according to Appendix 2-11 or Appendix 2-12, wherein a ratio of the width of the recess portion (96, 97) to the pitch (P) of the plurality of gate trenches (31) is 0.009 or more and 0.0133 or less.

### [Appendix 2-14]

The semiconductor device (1, 201) according to any one of Appendix 2-11 to Appendix 2-13, wherein a ratio of the width of the recess portion (96, 97) to a width (W₅) of a mesa portion (90) demarcated between the plurality of gate trenches (31) is 0.011 or more and 0.017 or less.

### [Appendix 2-15]

The semiconductor device (1, 201) according to any one of Appendix 2-11 to Appendix 2-14, further including a gate finger electrode (83) extending in the second direction in a region on the connection trench (21) and connected to the drawer portion (40).

### [Appendix 2-16]

The semiconductor device (1, 201) according to any one of Appendix 2-1 to Appendix 2-15, wherein a cross-sectional shape of the recess portion (96, 97) is an arc shape recessed toward the side surface (21a, 21b, 31a, 31b) side of the trench (21, 31).

### [Appendix 2-17]

The semiconductor device (1, 201) according to any one of Appendix 2-1 to Appendix 2-16, wherein the depth (D₃, D₄) of the recess portion (96, 97) is larger than the width (W₃, W₄) of the recess portion (96, 97).

### [Appendix 2-18]

The semiconductor device (1, 201) according to Appendix 2-17, wherein a ratio (W₃/D₃, W₄/D₄) of the width (W₃, W₄) of the recess portion (96, 97) to the depth (D₃, D₄) of the recess portion (96, 97) is 0.6 or more and less than 0.9.

### [Appendix 2-19]

The semiconductor device (1, 201) according to any one of Appendix 2-1 to Appendix 2-18, wherein a size of the semiconductor chip (2) is 0.5 mm square or more and 20 mm square or less.

### [Appendix 2-20]

The semiconductor device (1, 201) according to any one of Appendix 2-1 to Appendix 2-19, wherein a gate capacitance value of the semiconductor chip (2) is 300 pF or less.

1. A semiconductor device, comprising:
a semiconductor chip having a first principal surface and a second principal surface opposite to the first principal surface; and
a trench-type IGBT structure formed on the first principal surface of the semiconductor chip,
wherein the IGBT structure includes:
a trench formed in the first principal surface of the semiconductor chip and extending in a plurality of directions;
an insulating film formed on a side surface of the trench;
an embedded conductor embedded inside the trench through the insulating film; and
an intersection portion formed by the trenches extending in the plurality of directions, and
a curvature index of a corner portion of the intersection portion is 1.5 μm or more.

2. The semiconductor device according to claim 1, wherein a chamfer width of a virtual figure formed by an extension line of two sides forming the corner portion of the intersection portion is 0.4 μm or more.

3. The semiconductor device according to claim 1, wherein the curvature index of the corner portion of the intersection portion is 2.4 μm or less.

4. The semiconductor device according to claim 1, wherein a ratio of the curvature index of the corner portion of the intersection portion to a width of the trench is 1.5 or more.

5. The semiconductor device according to claim 4, wherein the ratio of the curvature index of the corner portion of the intersection portion to the width of the trench is 2.4 or less.

6. The semiconductor device according to claim 1, wherein the trenches extending in the plurality of directions include a first trench and a plurality of second trenches that intersect the first trench at the intersection portion, the plurality of second trenches being aligned in a stripe shape at intervals from each other, and
a ratio of the curvature index of the corner portion of the intersection portion to a pitch of the plurality of second trenches is 0.1 or more.

7. The semiconductor device according to claim 6, wherein the ratio of the curvature index of the corner portion of the intersection portion to the pitch of the plurality of second trenches is 0.16 or less.

8. The semiconductor device according to claim 1, wherein the trenches extending in the plurality of directions include a first trench and a plurality of second trenches that intersect the first trench at the intersection portion, the plurality of second trenches being aligned in a stripe shape at intervals from each other, and
a ratio of the curvature index of the corner portion of the intersection portion to a width of a mesa portion demarcated between the plurality of second trenches is 0.11 or more.

9. The semiconductor device according to claim 8, wherein the ratio of the curvature index of the corner portion of the intersection portion to the width of the mesa portion is 0.17 or less.

10. The semiconductor device according to claim 1, wherein the embedded conductor includes a gate embedded electrode that controls a channel of the IGBT structure, and
the semiconductor device includes a drawer portion integrally drawn out from the gate embedded electrode onto the first principal surface and covering the corner portion of the intersection portion.

11. The semiconductor device according to claim 1, wherein the trenches extending in the plurality of directions include a plurality of gate trenches aligned in a stripe shape at intervals in a first direction, each of the plurality of gate trenches extending in a second direction, and a connection trench extending in the first direction, connecting end portions in the second direction of the plurality of gate trenches to each other, and forming the T-shaped intersection portion at a connection portion with each of the gate trenches, and
the embedded conductor is integrally embedded in the gate trench and the connection trench, and
the semiconductor device includes a drawer portion drawn out from the embedded conductor onto the first principal surface and covering the corner portion of the intersection portion.

12. The semiconductor device according to claim 11, wherein widths of the gate trench and the connection trench are equal, and
a ratio of the curvature index of the corner portion of the intersection portion to the widths of the gate trench and the connection trench is 1.5 or more and 2.4 or less.

13. The semiconductor device according to claim 11, wherein a ratio of the curvature index of the corner portion of the intersection portion to a pitch of the plurality of gate trenches is 0.1 or more and 0.16 or less.

14. The semiconductor device according to claim 11, wherein a ratio of the curvature index of the corner portion of the intersection portion to a width of a mesa portion demarcated between the plurality of gate trenches is 0.11 or more and 0.17 or less.

15. The semiconductor device according to claim 11, further comprising: a gate finger electrode extending in the second direction in a region on the connection trench and connected to the drawer portion.

16. The semiconductor device according to claim 1, wherein a size of the semiconductor chip is 0.5 mm square or more and 20 mm square or less.

17. The semiconductor device according to claim 1, wherein a gate capacitance value of the semiconductor chip is 300 pF or less.

18. The semiconductor device according to claim 1, wherein the intersection portion includes a T-shaped intersection portion where the trenches extending in the plurality of directions intersect in a T-shape.

19. The semiconductor device according to claim 1, wherein the intersection portion includes an L-shaped intersection portion where the trenches extending in the plurality of directions intersect in an L-shape.

20. The semiconductor device according to claim 1, wherein the intersection portion includes a cross-shaped intersection portion where the trenches extending in the plurality of directions intersect in a cross-shape.
